(19) United States
(12) Patent Application Publication
(10) Pub. No.: US 2014/0149773 A1
(43) Pub. Date: May 29, 2014

(54) LATCH CIRCUIT AND DATA PROCESSING SYSTEM

(71) Applicant: Agency for Science, Technology and Research, Singapore (SG)

(72) Inventors: Kejie Huang, Singapore (SG); Huey Chian Foong, Singapore (SG)

(73) Assignee: Agency for Science, Technology and Research, Singapore (SG)

(21) Appl. No.: 14/092,975

(22) Filed: Nov. 28, 2013

Related U.S. Application Data
(60) Provisional application No. 61/731,050, filed on Nov. 29, 2012.

(51) Int. Cl. G11C 13/00; G06F 1/32

(52) U.S. Cl. CPC G11C 13/0069; G11C 13/0004; G11C 13/004; G06F 1/3234
USPC 713/323; 365/148; 365/163

(57) ABSTRACT

A latch circuit is described comprising a switchable resistive element and a switching circuit configured to set the switchable resistive element to a first resistive state in response to receiving a set signal and to set the switchable resistive element to a second resistive state in response to receiving a reset signal.

### FIELD OF THE INVENTION

Embodiments of the invention generally relate to a latch circuit and a data processing system.

### BACKGROUND OF THE INVENTION

To keep dynamic power constant across process generations, traditional MOSFET scaling theory prescribes reducing supply and threshold voltages in proportion to device dimensions, a practice that induces an exponential increase in sub-threshold leakage. As a result, leakage power has become comparable to dynamic power in current-generation processes, and will presumably soon exceed it in magnitude if voltages are scaled down any further. In many new high performance designs, the leakage component of power consumption is comparable to the switching component. Reports indicate that 40% or even higher percentage of the total power consumption is due to the leakage of transistors. This percentage can be expected to increase with technology scaling unless effective techniques are introduced to bring leakage under control.

To reduce the leaking component, multiple threshold voltage levels or well-bias control may be used. For example, a low-power circuit adopts an on-chip power-isolation switch (OPS) scheme, i.e., power gating. This scheme is very effective for reducing leakage when an LSI (large scale integrated) function block is in the standby state. However, it should typically be avoided that information is lost during a standby state.

Accordingly, approaches to reduce the leakage power without losing information during power off are desirable.

### SUMMARY OF THE INVENTION

In one embodiment, a latch circuit is provided including a switchable resistive element and a switching circuit configured to set the switchable resistive element to a first resistive state in response to receiving a set signal and to set the switchable resistive element to a second resistive state in response to receiving a reset signal.

According to a further embodiment, a data processing system is provided including a data processing circuit including a scan chain, a non-volatile memory and a controller configured to store, in response to a signal indicating that the data processing system is entering sleep mode, the content of the scan chain in the memory and to read, in response to a signal indicating the data processing system is leaving sleep mode, data from the memory and to store the data in the scan chain.

According to a further embodiment, a method for entering and leaving a sleep mode according to the data processing system described above is provided.

### SHORT DESCRIPTION OF THE FIGURES

Illustrative embodiments of the invention are explained below with reference to the drawings.

FIG. 1 shows an example for a memristor-based nonvolatile flip flop.

FIG. 2 shows a flip-flop with a shadow latch.

FIG. 3 shows a latch circuit.

FIG. 4 shows a data path of a digital circuit.

FIG. 5 shows a non-volatile latch according to an embodiment.

FIG. 6 shows a non-volatile flip-flop according to an embodiment.

FIG. 7 shows a unipolar write single cell resistive NVM latch.

FIG. 8 shows a unipolar write differential cell resistive NVM latch.

FIG. 9 shows a bipolar write single cell resistive NVM latch.

FIG. 10 shows a bipolar write differential cell resistive NVM latch.

FIG. 11 shows a unipolar write single cell resistive NVM latch with Q detection.

FIG. 12 shows a unipolar write differential cell resistive NVM latch with Q detection.

FIG. 13 shows a bipolar write single cell resistive NVM latch 300 with Q detection.

FIG. 14 shows a bipolar write differential cell resistive NVM latch with Q detection.

FIG. 15 shows a schematic of a bipolar write single cell resistive NVM latch with Q detection.

FIG. 16 shows simulation results for an asynchronous NVM latch with Q detection according to an embodiment.

FIG. 17 shows a schematic of a clocked bipolar write single cell resistive NVM latch without Q detection.

FIG. 18 shows a schematic of a clocked bipolar write single cell resistive NVM latch with Q detection.

FIG. 19 shows simulation results for a level sensing NVM latch with Q detection.

FIG. 20 shows simulation results for a level sensing NVM latch with Q detection.

FIG. 21 shows simulation results for a level sensing NVM latch with Q detection.

FIG. 22 shows a schematic of a bipolar write single cell resistive NVM latch.

FIG. 23 shows a schematic of a bipolar differential single cell resistive NVM latch.

FIG. 24 shows a schematic of a bipolar differential single cell resistive NVM latch.

FIG. 25 shows an asynchronous latch with Q detection.

FIG. 26 shows an edge trigger synchronous flip-flop with Q detection.

FIG. 27 shows an example for a Q detection circuit according to an embodiment.

FIG. 28 shows simulation results for the recovery with Q detection.

FIG. 29 shows simulation results for the recovery without Q detection.

FIG. 30 shows a test circuit.

FIG. 31 shows simulation results for the case that Q detection is always turned on.

FIG. 32 shows simulation results for the case that Q detection is disabled during recovery.

FIG. 33 shows a block diagram of a non-volatile shadow latch based retention register according to one embodiment.

FIG. 34 shows the read/write waveforms for the resistive non-volatile latch.

FIG. 35 shows a master latch, a slave latch and a resistive non-volatile latch.

FIG. 36 shows reading simulation results of a retention register with a bipolar write differential cells resistive NVM shadow latch.

FIG. 37 shows the writing simulation results of retention register with the bipolar write differential cells resistive NVM shadow latch.

FIG. 38 shows a leakage comparison between a nvFF according to an embodiment and a conventional retention flip-flop.

FIG. 39 shows a processing system according to an embodiment.

FIG. 40 shows a memory arrangement for a parallel writing without column address scheme.

FIG. 41 shows an example for a bidirectional driver for bipolar writing according to an embodiment.

FIG. 42 shows an example for a bidirectional driver for unipolar writing according to an embodiment.

FIG. 43 shows a processing system according to an embodiment.

FIG. 44 shows a memory arrangement for a parallel writing with column address scheme.

FIG. 45 shows an example for a bidirectional driver for bipolar writing according to an embodiment.

FIG. 46 shows an example for a bidirectional driver for unipolar writing according to an embodiment.

FIG. 47 shows a processing system according to an embodiment.

FIG. 48 shows a scan chain according to an embodiment.

FIG. 49 shows an arrangement of a scan chain and a memory array.

FIG. 50 shows a column address decoder according to an embodiment.

FIG. 51 shows a row address decoder according to an embodiment.

FIG. 52 shows a flow diagram.

FIG. 53 shows a scan chain arrangement illustrating that in the N bit parallel bus writing scheme a memory array can be shared among a plurality of digital blocks, e.g. in case of using a dedicated memory array.

### DETAILED DESCRIPTION

With the technology node scales down, the leakage current of a CMOS circuit typically dominate the percentage of power consumption, especially for standby power critical systems.

Certain methodologies can be used to reduce the leakage power without losing information during power off. One scheme is adding a nonvolatile memory (NVM) array to recode the information of an LSI (large scale integrated) block before standby, and read the data back from NVM array to this LSI block after power on. Another scheme is replacing the DFF (D-Flip-Flop) with hybrid CMOS/NVM flip-flops. In particular, if the function block circuitry is clock-synchronized, it is only necessary for all the Flip-Flops (F/F) to be nonvolatile. Therefore, nonvolatile Flip-Flops are desirable to achieve higher performance LSI circuits with low power consumption.

Employing nonvolatile Flip-Flops can provide a more efficient use of energy in circuits such as SoC (System on Chip) circuits for standby-power-critical and quick-startup applications such as battery operated appliances.

Unlike the case of SRAM or DRAM, resistive memories rely on non-volatile, resistive information storage in a cell, and thus exhibit near-zero leakage in the data array. RRAM (resistive random access memory), STT-RAM (spin transfer torque RAM) and PCM (phase change memory) are types of non-volatile memories which may be used to address many of the scaling problems and which are CMOS-compatible and offer fast read speeds, high density and write endurance. According to one embodiment, a switchable resistive element as used in such types of memories is used for non-volatile latch/flip-flop circuits to avoid off-state leakage current.

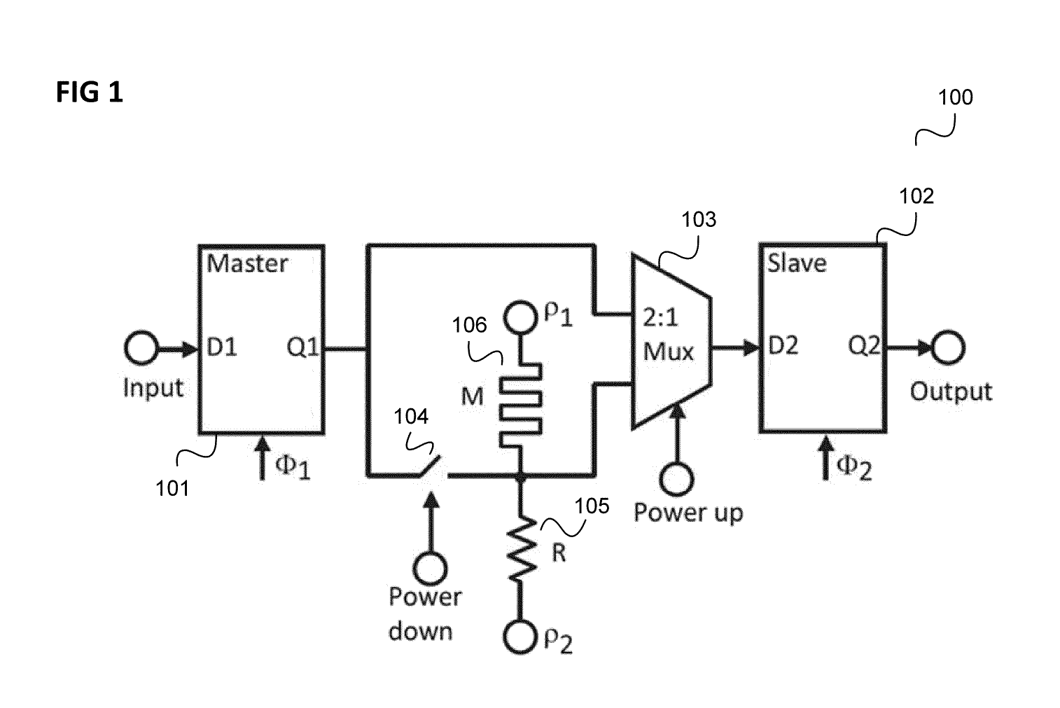

FIG. 1 shows an example for a memristor based nonvolatile flip flop 100.

The flip flop 100 includes a master latch 101 and a slave latch 102. The Q output of the master latch 101 is coupled via a 2:1 multiplexer 103 (i.e. a multiplexer with two inputs and one output) to the D-input of the slave latch 102, wherein the Q output of the master latch 101 is coupled directly to the first input of the multiplexer 103 and via a switch 104 to the second input of the multiplexer 103. Further, a resistor 105 and a memristor 106 are coupled to the second input of the multiplexer 103. Upon reception of a power down signal, which controls the switch 104, the memristor saves the state of the flip flop 100. The multiplexer 103 is controlled by a power up signal.

It should be noted that magnetic non-volatile flip-flops (e.g. based on a memristor) typically require serial writing of two magnetic tunnel junctions (MTJs) which require a higher power supply (almost double) and leads to high power consumption. Accordingly, this approach may require thick oxide and level shift to support the high power supply which reduces the possible densities of non-volatile flip-flop cells based on this approach. Moreover, the asymmetrical write condition for the P (parallel) and AP (anti-parallel) phase may lead to failure in the programming or it lead to an over stressed both in time and voltage. The over stress of the MTJs may increase the break down probability.

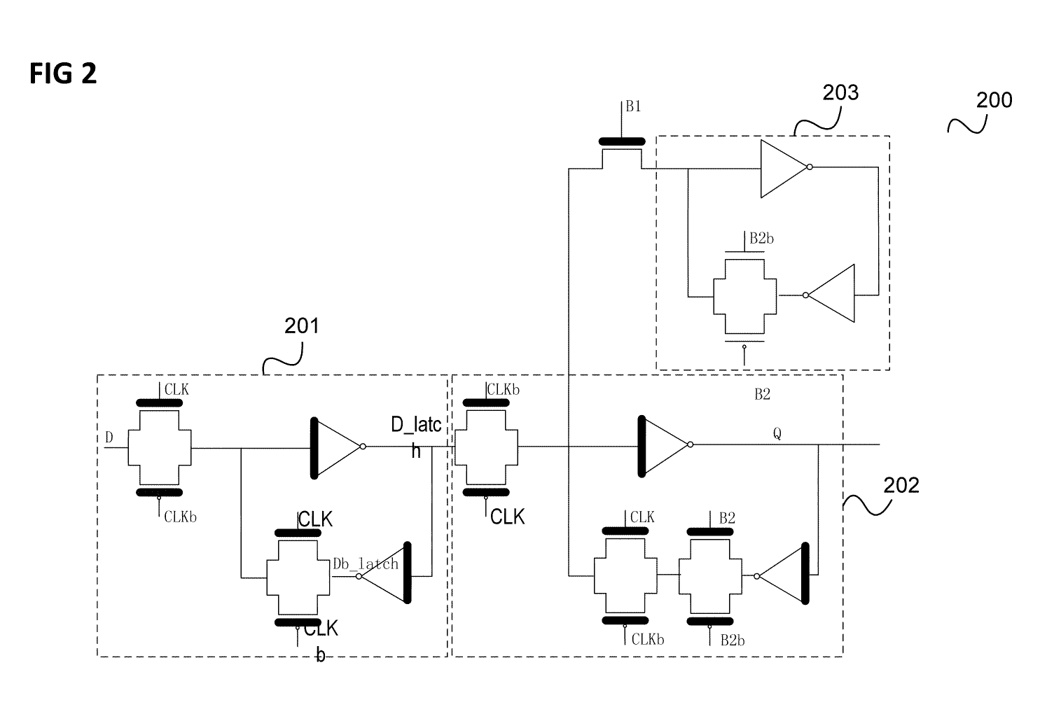

The state of a flip-flop may for example be saved during power off by using a power gated D-flip-flop in combination with a retention register as shown in FIG. 2.

FIG. 2 shows a flip-flop 200 with a shadow latch.

The flip-flop 200 includes a master latch 201 and a slave latch 202. Further, the flip-flop 200 includes a shadow latch 203. Both the input of the slave latch 202 and the shadow latch are connected to the output of the master latch 201.

The flip-flop 200 implements a retention register that allows efficiently reducing the leakage current during power off state without losing the flip-flop's information. However, the standby power consumption of the retention register cannot be ignored. This power consumption may for example reduce the life time of the battery of a mobile device in which it is used.

In view of the above, according to various embodiments, two approaches to reduce standby power consumption are disclosed. According to the first approach, a nonvolatile flip-flop is used as retention register for a low power circuit design.

According to the second approach the states of registers (i.e. the states of flip-flops) are stored in a non-volatile memory by means of a scan chain. A scan chain can be understood as a serial connection of flip-flops (registers) or latches which for example store data to be processed or resulting from a processing by one or more digital processing blocks. Both approaches allow efficiently reducing the standby power consumption.

According to various embodiments, two forms of non-volatile latches/flip-flops (or registers) may be used. According to various embodiments, they can be implemented as hybrid NVM based latches/flip-flops. The first form is a non-volatile flip-flop with real time record capability. The second form can be seen to be based on a non-volatile shadow latch.

It should be noted that in the following, flip-flop may be understood as including multiple stages, such as a master latch, a slave latch and for example a shadow latch. However, a flip-flop may also be understood as a flip-flop with a single stage, such as a D-flip-flop (e.g. corresponding to one of the stages of the flip-flops shown in FIGS. 1 and 2). A flip-flop (or register) may be understood to be clock edge-triggered. A latch may be understood to be state triggered.

According to the first form of non-volatile flip-flop provided according to one embodiment a non-volatile cell is integrated in or between a master and a slave latch. The non-volatile cell may update its state every clock cycle. A Q detection function (i.e. a function checking the current output of the flip-flop) may be used to reduce power consumption of the non-volatile flip-flop. This form of non-volatile flip-flop allows real time record and fast recovery at practically zero standby power consumption and with high reliability. It may protect data from accidental power off. The first form of non-volatile flip-flop may reduce the operational speed and power consumption. Its power consumption merit is determined by the power on/off duty cycle.

According to the second form of non-volatile flip-flop, a non-volatile latch is used in place of a shadow latch. According to the second form of non-volatile flip-flop, it only updates the states of the NV cells just before the circuits or system powered off and restores the data from NV cells to registers after the circuits or system powered on. Since it only update once during power modes transition, it is not necessary to detect the Q of the FF. The advantages of the nvFF (non-volatile flip-flop) of form 2 is that the penalty to normal operation speed and power consumption has been minimized. The area is smaller than the nvFF of form 1. The disadvantage is it requires additional control signal to retain and restore the states. Its power consumption merit is determined by standby time width (i.e. standby duration).

According to one embodiment, a scan based approach is used to store the states of registers in a dedicated non-volatile memory (NVM) array. This dedicated NVM array is for example only used to store the information of the registers during standby. The information of the registers is retained in the NVM array and restored from the NVM array through a scan chain. A dedicated NVM array allows implementation with compact area, high reliability and low retain/restore power consumption. Compared to retaining states by means of non-volatile cells included in flip-flops, the approach based on a NVM array requires longer time to retain and restore the register states. Moreover, it may require a more complex controller circuit. Its power consumption merit is also determined by the standby time width.

It should be noted that the approach based on an NVM array can be implemented with less chip area overhead compared to the usage of non-volatile flip-flops. The reliability of the approach based on an NVM array may be enhanced by means of using an ECC (error correction code) algorithm.

It should further be noted that for an implementation of the approaches, the usage of MTCMOS (multi-threshold complementary metal oxide semiconductor) is not compulsory.

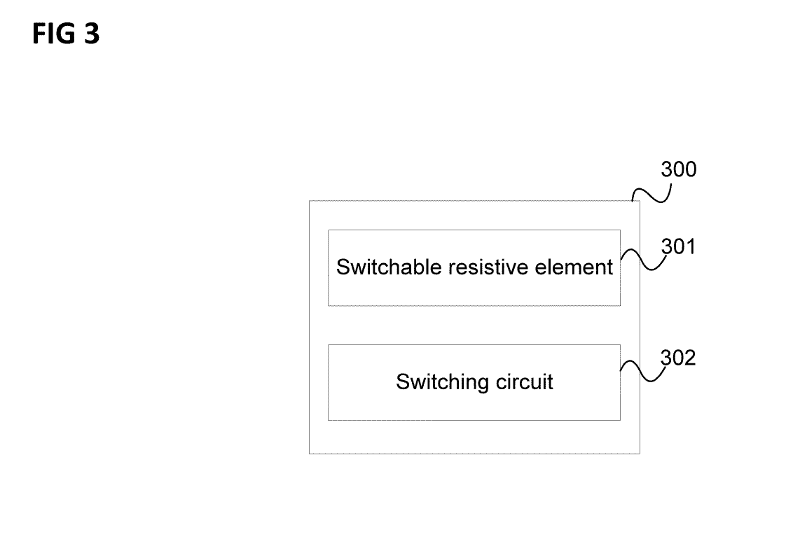

According to one embodiment, a resistive non-volatile memory based flip-flop is provided. This is illustrated in FIG. 3.

FIG. 3 shows a latch circuit 300.

The latch circuit 300 includes a switchable resistive element 301.

The latch circuit 300 further includes a switching circuit 302 configured to set the switchable resistive element to a first resistive state in response to receiving a set signal and to set the switchable resistive element to a second resistive state in response to receiving a reset signal.

In other words, according to one embodiment, the state of a latch (or flip-flop) is retained by a setting the resistance state of a switchable resistive element. The switchable resistive element can be understood as a memory cell of a resistive non-volatile memory.

The latch circuit 300 may for example be used as a part of a non-volatile flip-flop.

The latch circuit may for example include an input configured to receive a signal, wherein the set signal corresponds to the signal having a first value and the reset signal corresponds to the signal having a second value.

For example, one of the first value and the second value is a logical 1 and the other of the first value and the second value is a logical 0.

According to one embodiment, the latch circuit further includes a set input and a reset input, wherein the switching circuit is configured to set the switchable resistive element to a first resistive state in response to receiving the set signal and to set the switchable resistive element to a second resistive state in response to receiving the reset signal via the reset input.

The switching circuit is for example configured to detect whether the switchable resistive element is in the first resistive state and to switch the switchable resistive element into the first resistive state in response to receiving a set signal if it has detected that the switchable resistive element is not in the first resistive state.

According to one embodiment, the switching circuit is configured to detect whether the switchable resistive element is in the second resistive state and to switch the switchable resistive element into the second resistive state in response to receiving a reset signal if it has detected that the switchable resistive element is not in the second resistive state.

The switchable resistive element for example includes material showing a resistive switching effect.

For example, the switchable resistive element includes phase change material.

According to one embodiment, the switching circuit is configured to set the switchable resistive element to the first resistive state by a applying a first voltage or current to the switchable resistive element and to reset the switchable resistive element to the second resistive state by a applying a second voltage or current to the switchable resistive element.

The first voltage or current and the second voltage or current for example differ in at least one of magnitude and polarity (i.e. direction).

The latch circuit may further include an output circuit configured to output a signal representing the resistive state of the switchable resistive element.

For example, the output circuit includes a slave latch.

The latch circuit may further include an input circuit configured to receive an input and to provide, depending on the input, the set signal or the reset signal to the switching circuit.

For example, the input circuit includes a master latch.

According to one embodiment, the latch circuit includes a master latch, a slave latch and a shadow latch, wherein the shadow latch includes the switchable resistive element and the switching circuit and is configured to output a signal representing the resistive state of the switchable resistive element to the slave latch.

For example, the shadow latch is configured to output a signal representing the resistive state of the switchable resistive element to the slave latch in response to a restore signal.

For example, the switching circuit is configured to receive one of the set signal and the reset signal from the master latch in response to a retain signal.

It should be noted that the features of the various examples and embodiments described may be used in any combination.

In the following, embodiments are described in more detail.

According to one embodiment, a non-volatile memory is integrated into a logic circuit to realize standby power consumption free circuits.

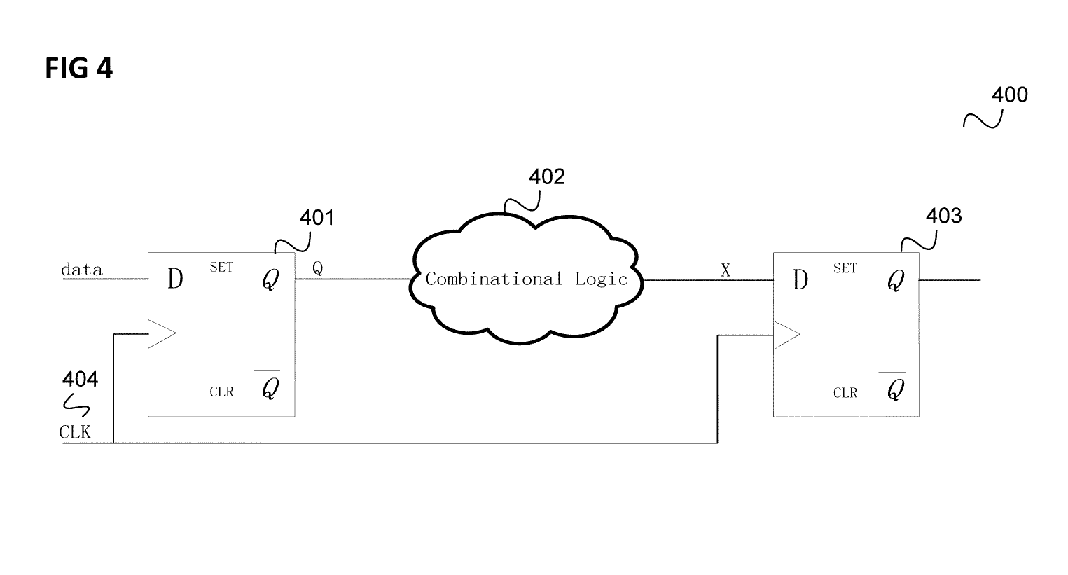

FIG. 4 shows a data path 400 of a digital circuit.

The data path includes a first flip-flop 401 and a second flip-flop 403 which are connected by a combinational logic 402. In this example, the circuitry is clock-synchronized by means of a common clock signal 404 fed to both flip-flops 401, 403. In such a case data may be retained by implementing all the flip-flops 401, 403 to be non-volatile.

The flip-flops 401, 403 may each be part of a scan chain.

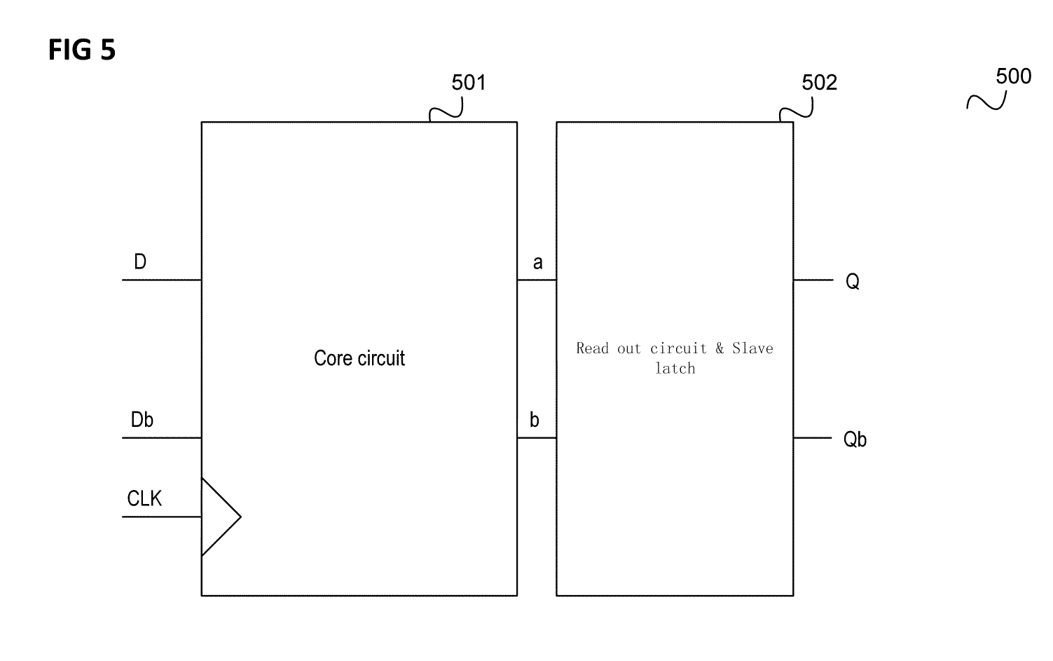

FIG. 5 shows a non-volatile latch 500 according to an embodiment.

The non-volatile latch 500 includes a core circuit 501 and a slave latch 502.

The core circuit 501 has a D input (to receive the value to be stored by the latch 500), a Db input (to receive the inverted value of the value input via the D input) and a clock (CLK) input. The core circuit 501 further has a first output a and a second output b.

The slave latch 502 has a first input a connected to the first output a of the core circuit 501 and a second input b connected to the second output b of the core circuit 501.

The slave latch 502 further has a Q output and a Qb output which form the output and inverted output of the latch 500.

It should be noted that it may not be possible to control the slave latch by the clock for a synchronous latch with Q detection function.

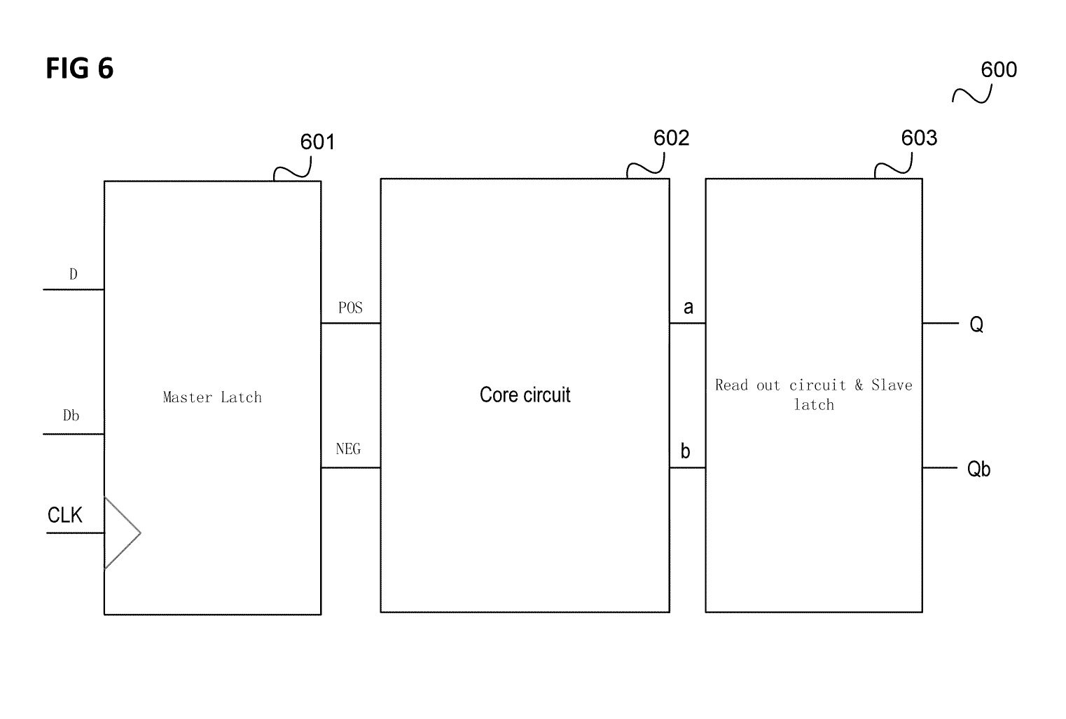

FIG. 6 shows a non-volatile flip-flop 600 according to an embodiment.

The non-volatile flip-flop 600 is for example an edge triggered flip-flop.

The non-volatile flip-flop 600 includes a master latch 601, a core circuit 602 and a slave latch 603.

The master latch 601 has a D input (to receive the value to be stored by the flip-flop 600), a Db input (to receive the inverted value of the value input via the D input) and a clock (CLK) input. The master latch 601 further has a first output POS and a second output NEG.

The core circuit 602 has a first input POS connected to the first output POS of the master latch 601 and a second input NEG connected to the second output NEG of the master latch 601.

The core circuit 602 further has a first output a and a second output b.

The slave latch 603 has a first input a connected to the first output a of the core circuit 602 and a second input b connected to the second output b of the core circuit 602.

The slave latch 603 further has a Q output and a Qb output which form the output and inverted output of the flip-flop 600.

The slave latch 502, 603, may also be used as a sense amplifier.

The core circuit 501, 602 may for example be supplied by a positive current source and a negative current source.

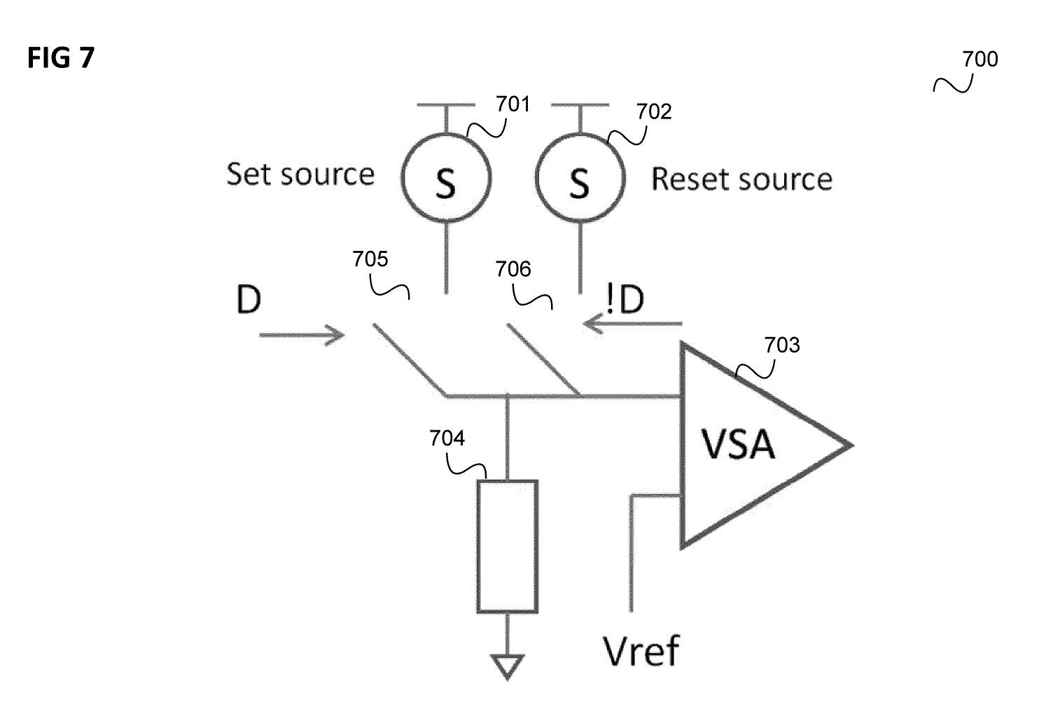

Examples for the core circuit 501, 602 are described in the following with reference to FIGS. 7 to 10.

FIG. 7 shows a unipolar write single cell resistive NVM latch 700.

The latch 700 includes a set source 701, a reset source 702 and a differential voltage sense amplifier (VSA) 703 with two inputs.

The state of the latch 700 is stored by a unipolar switchable resistive element 704. The switchable resistive element 704 is connected between ground and the first input of the VSA 703. The switchable resistive element 704 is connected to the set source 701 by means of a first switch 705 in response of a value 1 (i.e. true or high) at the D input and is connected to the reset source 702 by means of a second switch 706 in response to a value 1 at the Db (also referred to as !D) input.

The second input of the VSA 703 is connected to a reference voltage Vref.

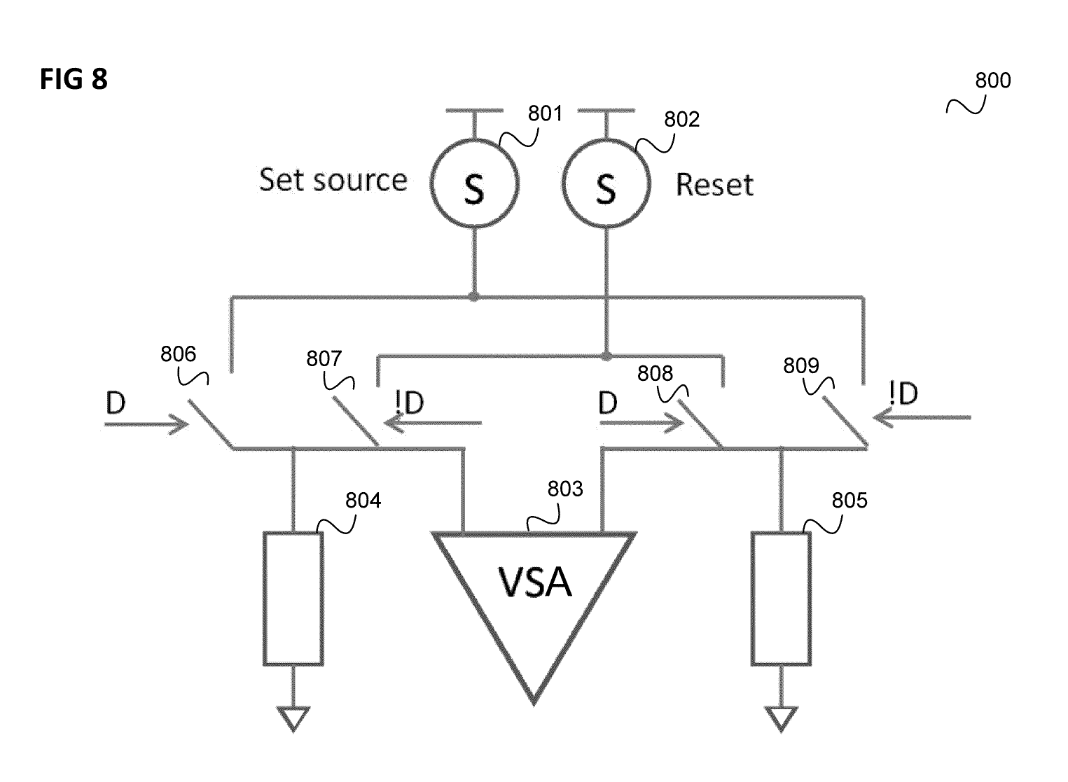

FIG. 8 shows a unipolar write differential cell resistive NVM latch 800.

The latch 800 includes a set source 801, a reset source 802 and a differential voltage sense amplifier (VSA) 803 with two inputs.

The state of the latch 800 is stored by a first unipolar switchable resistive element 804 and a second unipolar switchable resistive element 805.

The first switchable resistive element 804 is connected between ground and the first input of the VSA 803. The first switchable resistive element 804 is connected to the set source 801 by means of a first switch 806 in response of a value 1 at the D input and is connected to the reset source 802 by means of a second switch 807 in response to a value 1 at the Db input.

The second switchable resistive element 805 is connected between ground and the second input of the VSA 803. The second switchable resistive element 805 is connected to the set source 801 by means of a third switch 808 in response of a value 1 at the Db input and is connected to the reset source 802 by means of a fourth switch 809 in response to a value 1 at the D input.

It should be noted that for the differential cell architecture as in the example of FIG. 8 an additional sense amplifier or recovery circuit is not necessary.

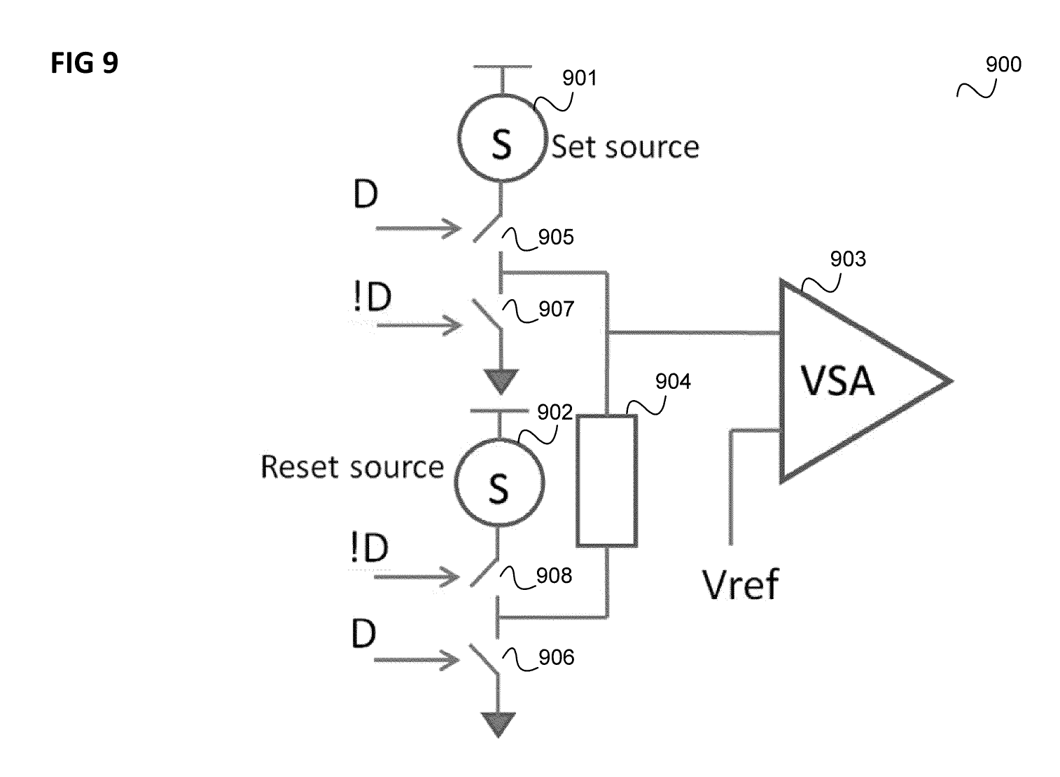

FIG. 9 shows a bipolar write single cell resistive NVM latch 900.

The latch 900 includes a set source 901, a reset source 902 and a differential voltage sense amplifier (VSA) 903 with two inputs.

The state of the latch 900 is stored by a bipolar switchable resistive element 904. The switchable resistive element 904 is connected to the first input of the VSA 903. The switchable resistive element 704 is connected between the set source 901 and ground by means of a first switch 905 and a second switch 906 in response of a value 1 at the D input and is connected between the reset source 902 and ground by means of a third switch 907 and a fourth switch 908 in response to a value 1 at the Db input.

The second input of the VSA 903 is connected to a reference voltage Vref.

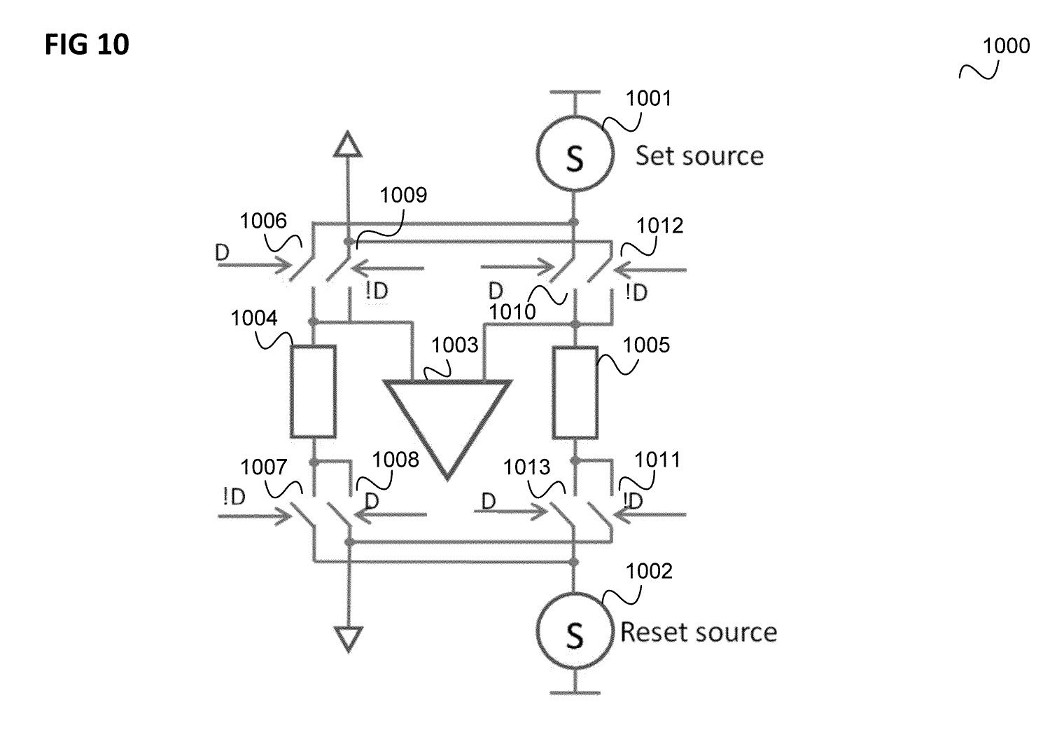

FIG. 10 shows a bipolar write differential cell resistive NVM latch 1000.

The latch 1000 includes a set source 101, a reset source 102 and a differential voltage sense amplifier (VSA) 1003 with two inputs.

The state of the latch 1000 is stored by a first bipolar switchable resistive element 1004 and a second bipolar switchable resistive element 1005.

The first switchable resistive element 1004 is connected to the first input of the VSA 1003. The switchable resistive element 1004 is connected between the set source 1001 and ground by means of a first switch 1006 and a second switch 1008 in response of a value 1 at the D input and is connected between the reset source 1002 and ground by means of a third switch 1007 and a fourth switch 1009 in response to a value 1 at the Db input.

The second switchable resistive element 1005 is connected to the second input of the VSA 1003. The second switchable resistive element 1005 is connected between the set source 1001 and ground by means of a fifth switch 1010 and a sixth switch 1011 in response of a value 1 at the Db input and is connected between the reset source 1002 and ground by means of a seventh switch 1012 and an eighth switch 1013 in response to a value 1 at the Db input.

The latches 700, 800, 900, 1000 may also be implemented with Q detection. In this case, instead of a switch of the latches 700, 800, 900, 1000 being closed in response of a value of 1 of D, the switch is closed in response to a value of 1 of D & !Q (i.e. D and not Q) and in case of a switch being closed in response of a value of 1 of Db, the switch is closed in response to a value of 1 of !D & Q (i.e. not D and Q).

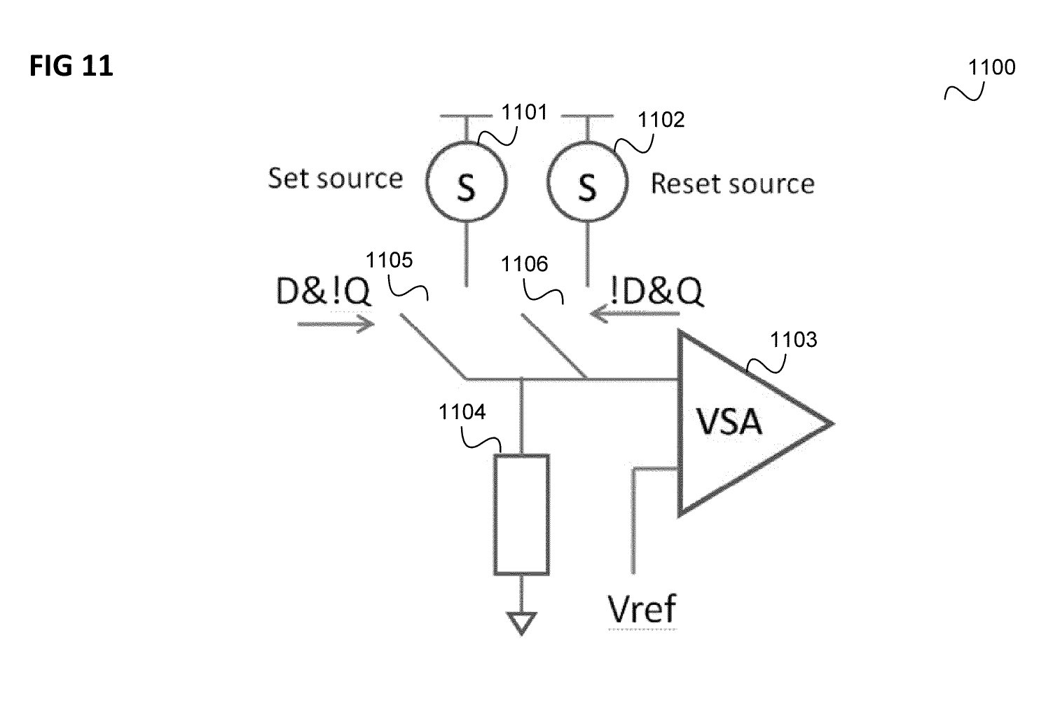

This is illustrated in FIGS. 11 to 14.

FIG. 11 shows a unipolar write single cell resistive NVM latch 1100 with Q detection.

The latch 1100 corresponds to the latch 700 except for the switches being closed by D&!Q and !D&Q as explained above.

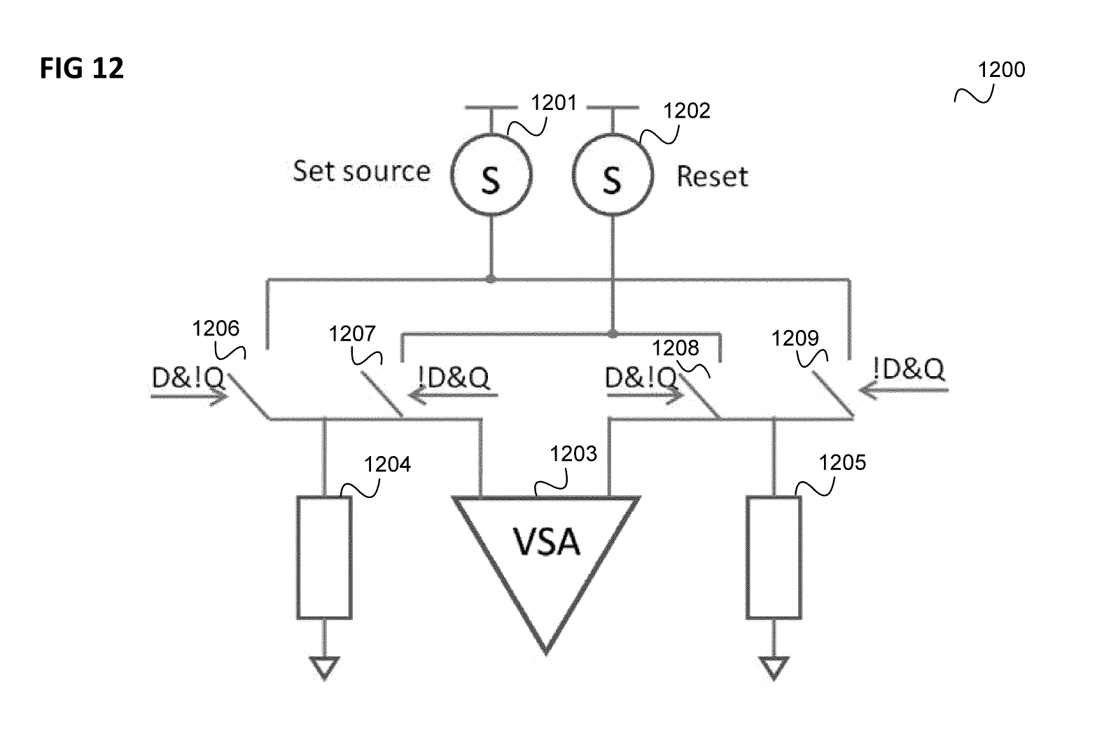

FIG. 12 shows a unipolar write differential cell resistive NVM latch 1200 with Q detection.

The latch 1200 corresponds to the latch 800 except for the switches being closed by D&!Q and !D&Q as explained above.

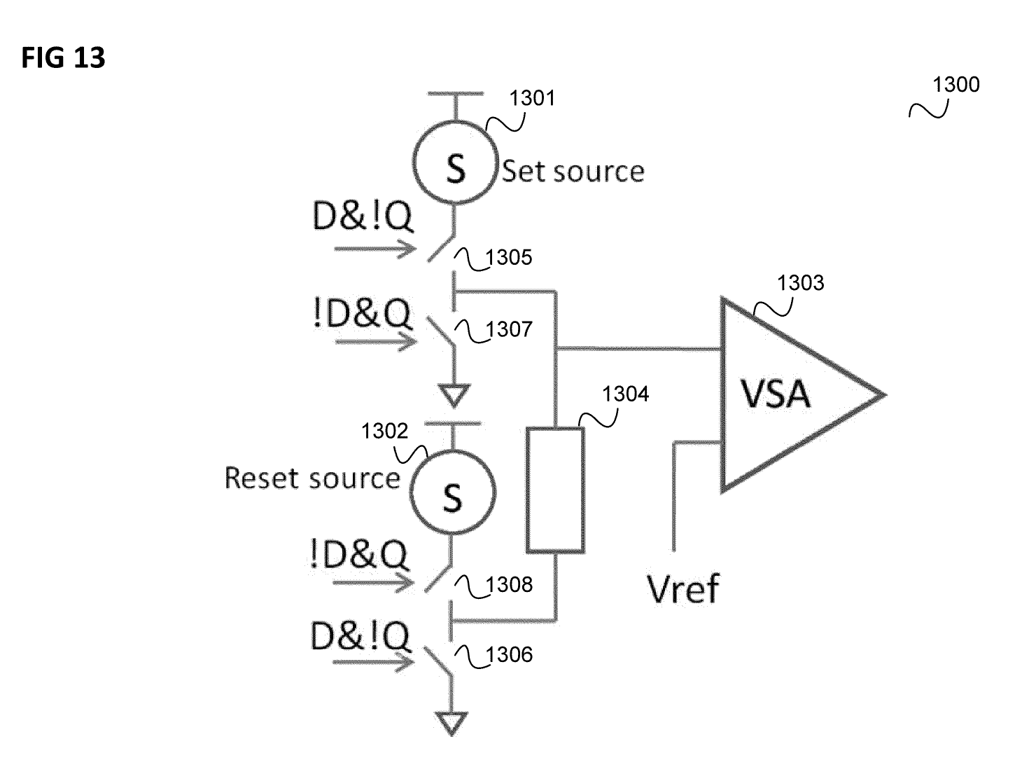

FIG. 13 shows a bipolar write single cell resistive NVM latch 1300 with Q detection.

The latch 1300 corresponds to the latch 900 except for the switches being closed by D&!Q and !D&Q as explained above.

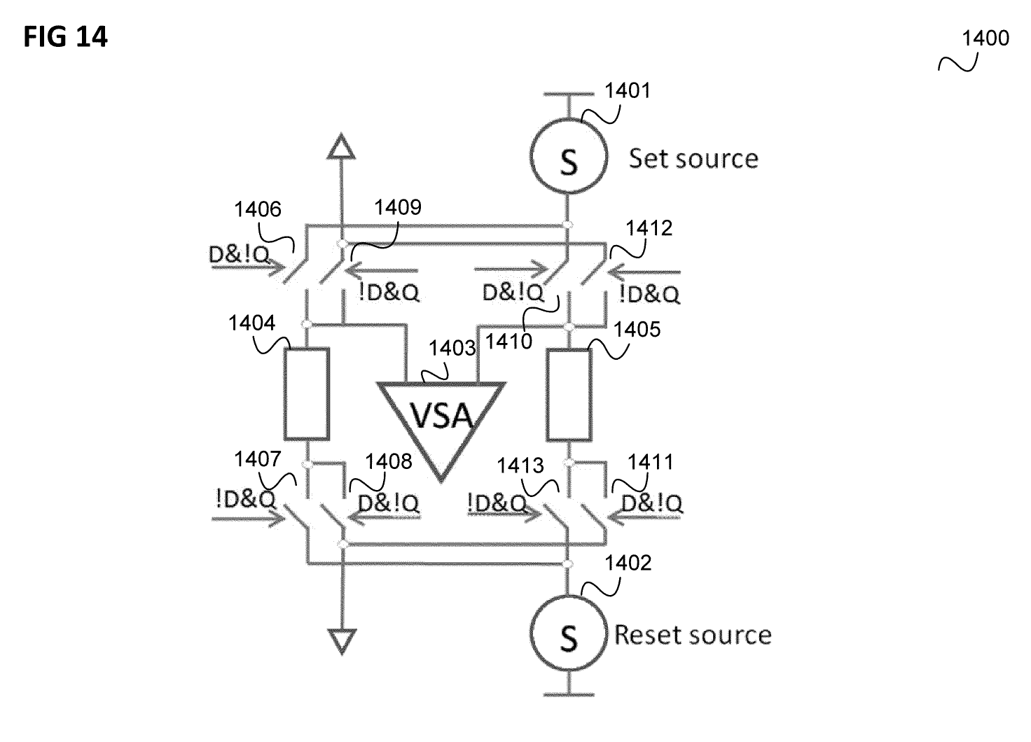

FIG. 14 shows a bipolar write differential cell resistive NVM latch 1400 with Q detection.

The latch 1400 corresponds to the latch 1000 except for the switches being closed by D&!Q and !D&Q as explained above.

Q detection allows avoiding turning on the write path (i.e. connecting a switchable resistive element with a set source) if Q has been synchronized with D or turning off the write path immediately after Q has been synchronized with D. This further reduces power consumption and increases the life cycle of the switchable resistive element.

The set sources and reset sources of the latches 700 to 1400 can be voltage source or current source.

The switchable resistive elements of the latches 700 to 1400 can be switchable resistive elements according to any resistive non-volatile memory cell, including Phase Change Memory (PCM), Resistive RAM (RRAM) and Spin-transfer torque MRAM (STT-MRAM). The type of switchable resistive element determines whether a unipolar or bipolar write scheme is used.

The voltage sense amplifier of the latches 700 to 1400 allows reading out the data from the non-volatile cells (i.e. the state of the respective latch 700 to 1400), e.g. to slave latch 502, 603 via output a (output b may for example be configured to have the negated state of output a). For this, a current may for example be applied to the resistive element (e.g. by an additional current source, not shown in FIGS. 7 to 14) of latches 700 to 1400 and the reference voltage Vref may be chosen to allow determining the resistive state of the switchable resistive element (e.g. high resistance HR or low resistance LR) by comparison of the resulting voltage at the resistive element and the reference voltage.

To save chip area, the slave latch 502, 603 may be used as part of the sense amplifier.

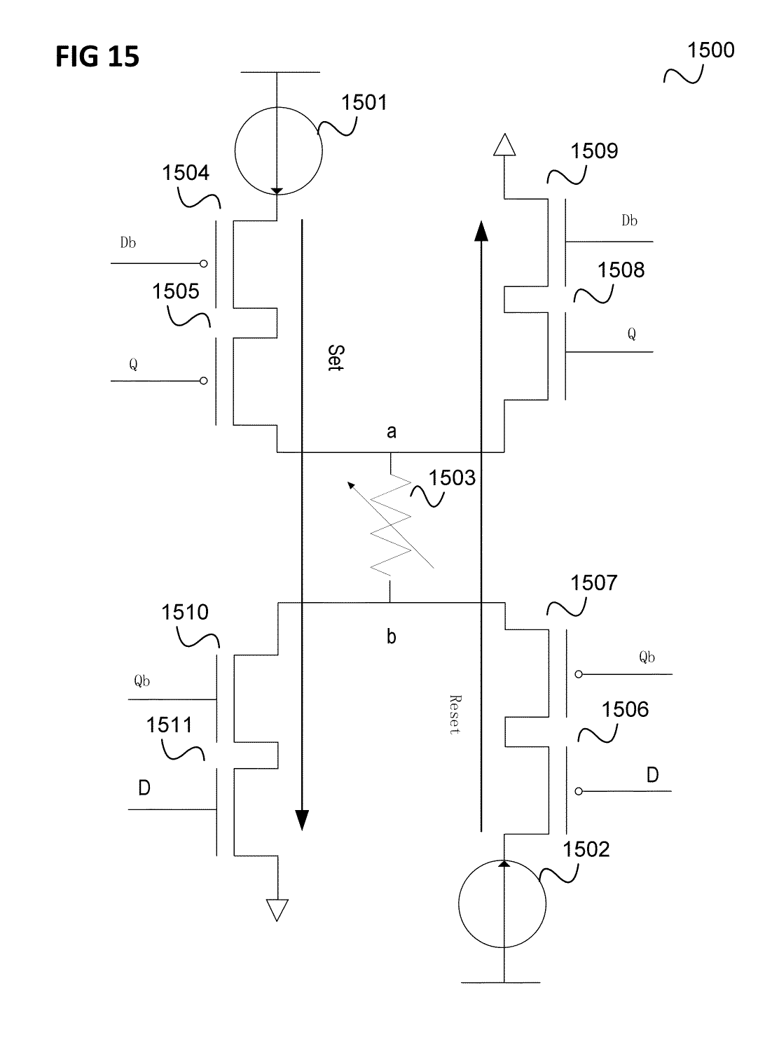

An implementation example of a bipolar write single cell resistive NVM latch with Q detection (i.e. for latch 1300) is described in the following with reference to FIG. 15.

FIG. 15 shows a schematic of a bipolar write single cell resistive NVM latch 1500 with Q detection.

The latch 1500 includes a set voltage source 1501, a reset voltage source 1502 and a switchable resistive element 1503 connected between an a output and a b output of the latch 1500.

The set voltage source 1501 is connected between ground and the source terminal of a first p channel field effect transistor (FET) 1504 whose gate is connected to the Db input.

The drain terminal of the first p channel FET 1504 is connected to the source terminal of a second p channel FET 1505 whose gate is connected to the Q output.

The drain terminal of the second p channel FET 1505 is connected to the a output.

The reset voltage source 1502 is connected between ground and the source terminal of a third p channel FET 1506 whose gate is connected to the D input.

The drain terminal of the third p channel FET 1506 is connected to the source terminal of a fourth p channel FET 1507 whose gate is connected to the Qb output.

The drain terminal of the fourth p channel FET 1507 is connected to the b output.

The a output is further connected to the drain terminal of a first n channel FET 1508 whose gate terminal is connected to the Q output. The source terminal of the first n channel FET 1508 is connected to the drain terminal of a second n channel FET 1509 whose gate terminal is connected to the Db input and whose source terminal is connected to ground.

The b output is further connected to the drain terminal of a third n channel FET 1510 whose gate terminal is connected to the Qb output. The source terminal of the third n channel FET 1510 is connected to the drain terminal of a fourth n channel FET 1511 whose gate terminal is connected to the D input and whose source terminal is connected to ground.

For example, an asynchronous latch may be implemented by replacing the core circuit 501 by the latch 1500.

The truth table of the latch 1500 is given by Table 1.

TABLE 1
Mode truth table of asynchronous NVM latch with Q
detection

| D | Q | Q′ | Reset | Set | Phase |
|---|---|---|---|---|---|
| 0 | 0 | 0 | 0 | 0 | — |
| 0 | 1 | 0 | 1 | 0 | HR→LR |
| 1 | 0 | 1 | 0 | 1 | LR→HR |
| 1 | 1 | 1 | 0 | 0 | — |

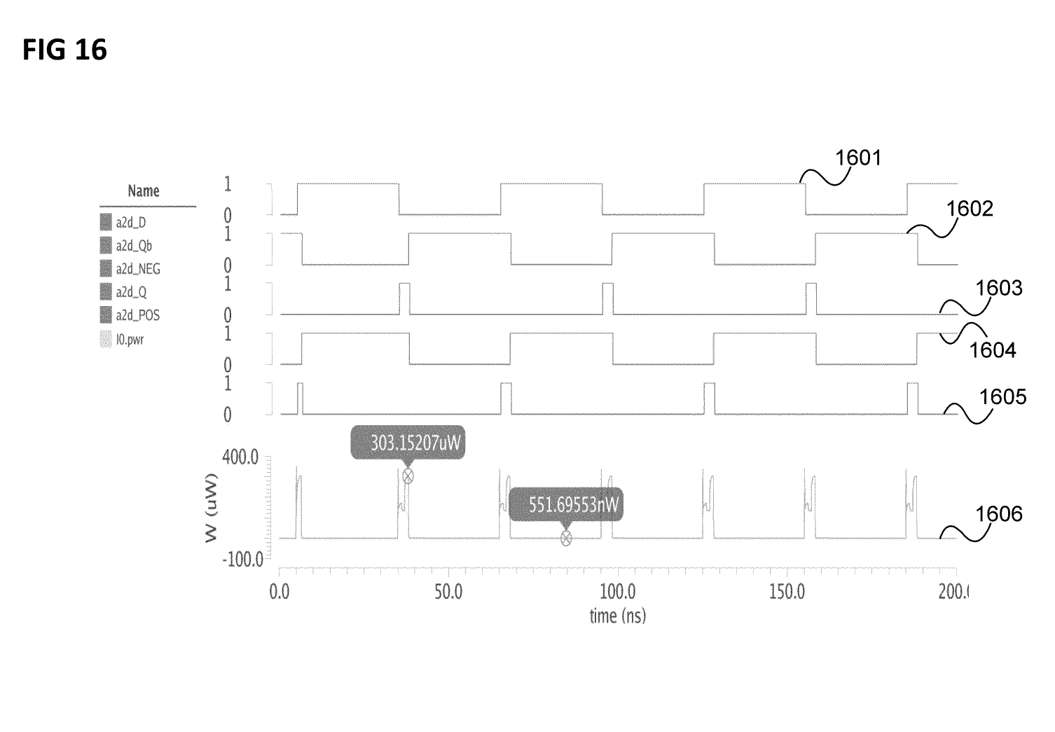

Results of a simulation of the behavior of the latch 1500 are given in FIG. 16.

FIG. 16 shows simulation results for an asynchronous NVM latch with Q detection according to an embodiment.

In FIG. 16, time increases from left to right.

A first graph 1601 shows the behavior of the signal at the D input.

A second graph 1602 shows the behavior of the signal at the Qb output.

A third graph 1603 shows the behavior of NEG=!D & Q.

A fourth graph 1604 shows the behavior of Q.

A fifth graph 1605 shows the behavior of POS=D & !Q.

A sixth graph 1606 shows the behavior of the consumed power.

The state of the latch 1500 is not changed if D=Q. Otherwise, a SET or RESET pulse is conducted to the NVM cell, i.e. the switchable resistive element 1503. Once the state of the NVM cell has been successfully updated, the write path is automatically turned off, as can be seen in FIG. 16.

The various latches (e.g. as illustrated in FIGS. 7 to 14) may be implemented synchronously (i.e. clocked) or asynchronously (i.e. not clocked).

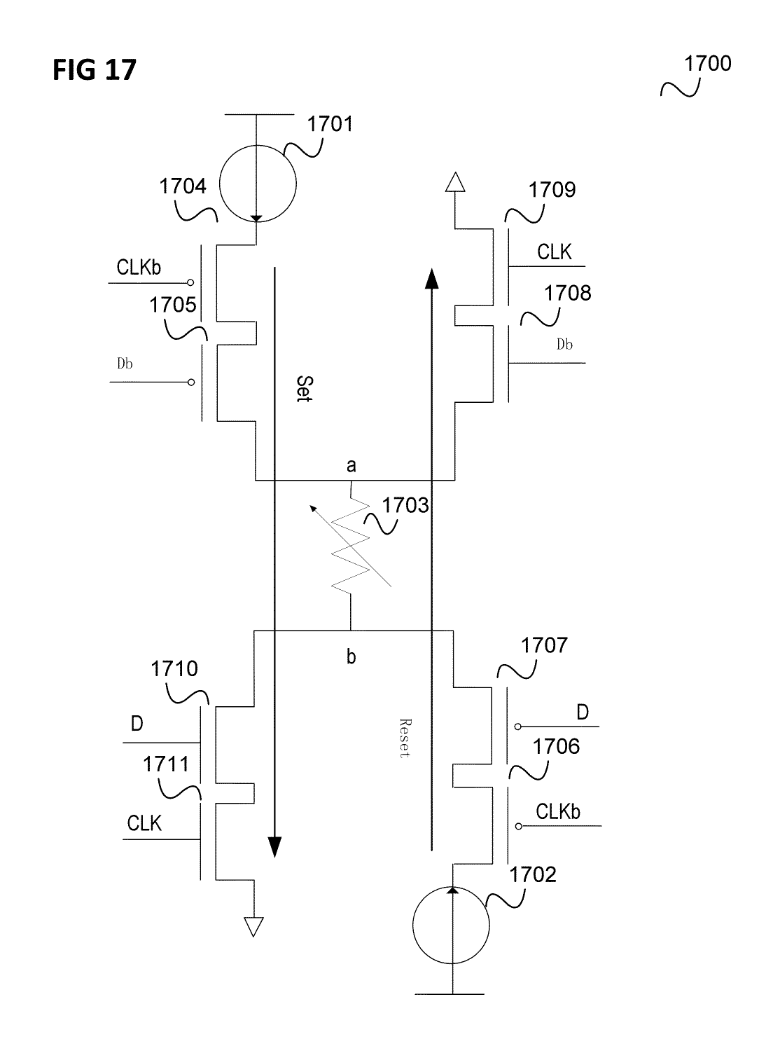

FIG. 17 shows a schematic of a clocked bipolar write single cell resistive NVM latch without Q detection.

The latch 1700 includes a set voltage source 1701, a reset voltage source 1702 and a switchable resistive element 1703 connected between an a output and a b output of the latch 1700.

The set voltage source 1701 is connected between ground and the source terminal of a first p channel field effect transistor (FET) 1704 whose gate is supplied with CLKb (negated clock signal).

The drain terminal of the first p channel FET 1704 is connected to the source terminal of a second p channel FET 1705 whose gate is connected to the Db input.

The drain terminal of the second p channel FET 1705 is connected to the a output.

The reset voltage source 1702 is connected between ground and the source terminal of a third p channel FET 1706 whose gate is supplied with CLKb.

The drain terminal of the third p channel FET 1706 is connected to the source terminal of a fourth p channel FET 1707 whose gate is connected to the D input.

The drain terminal of the fourth p channel FET 1707 is connected to the b output.

The a output is further connected to the drain terminal of a first n channel FET 1708 whose gate terminal is connected to the Db input. The source terminal of the first n channel FET 1708 is connected to the drain terminal of a second n channel FET 1709 whose gate terminal is supplied with CLK and whose source terminal is connected to ground.

The b output is further connected to the drain terminal of a third n channel FET 1710 whose gate terminal is connected to the D input. The source terminal of the third n channel FET 1710 is connected to the drain terminal of a fourth n channel FET 1711 whose gate terminal is supplied with CLK and whose source terminal is connected to ground.

For example, a synchronous non-volatile latch/flip-flop without Q detection may be implemented by replacing the core circuit 501, 602 by the latch 1700.

The truth table of the latch 1700 is given by Table 2.

TABLE 2
Operation mode truth table for synchronous
latch/flip-flop without Q detection

| CLK | D | Q | Q′ | Reset | Set | Phase |
|---|---|---|---|---|---|---|
| ↑ | 0 | 0 | 0 | 1 | 0 | — |
| ↑ | 0 | 1 | 0 | 1 | 0 | HR→LR |
| ↑ | 1 | 0 | 1 | 0 | 1 | LR→HR |
| ↑ | 1 | 1 | 1 | 0 | 1 | — |

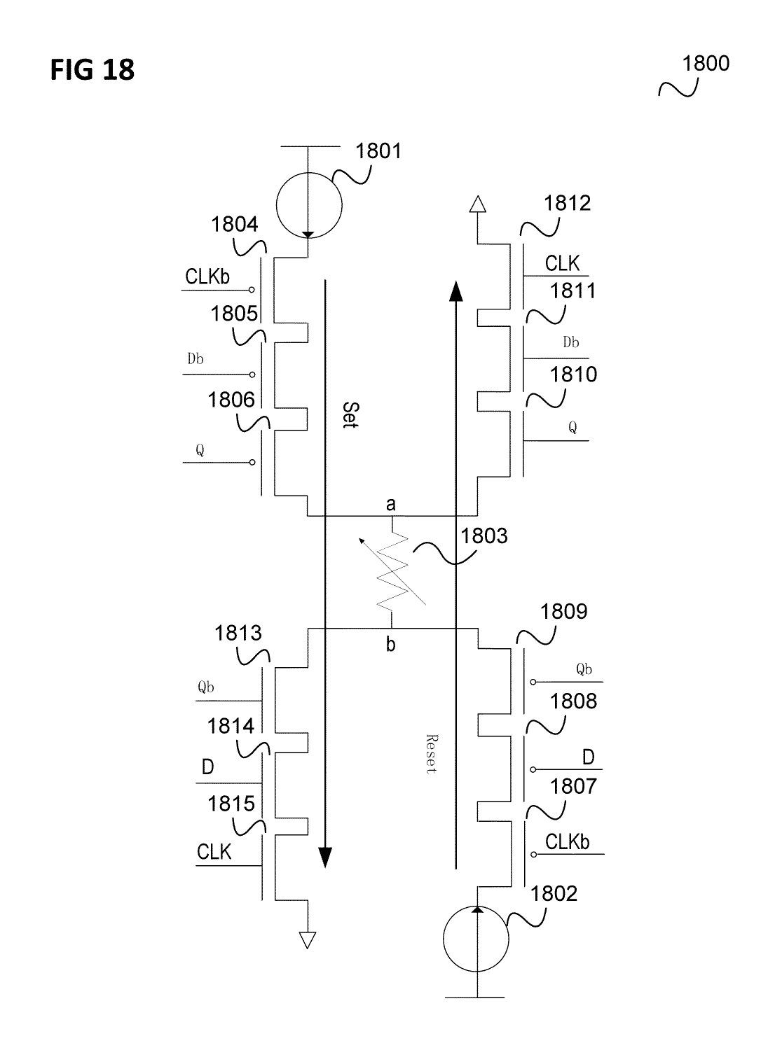

FIG. 18 shows a schematic of a clocked bipolar write single cell resistive NVM latch with Q detection.

The latch 1800 includes a set voltage source 1801, a reset voltage source 1802 and a switchable resistive element 1803 connected between an a output and a b output of the latch 1800.

The set voltage source 1801 is connected between ground and the source terminal of a first p channel field effect transistor (FET) 1804 whose gate is supplied with CLKb (negated clock signal).

The drain terminal of the first p channel FET 1804 is connected to the source terminal of a second p channel FET 1805 whose gate is connected to the Db input.

The drain terminal of the second p channel FET 1805 is connected to the source terminal of a third p channel FET 1806 whose gate is connected to the Q output.

The drain terminal of the third p channel FET 1806 is connected to the a output.

The reset voltage source 1802 is connected between ground and the source terminal of a fourth p channel FET 1807 whose gate is supplied with CLKb.

The drain terminal of the fourth p channel FET 1807 is connected to the source terminal of a fifth p channel FET 1808 whose gate is connected to the D input.

The drain terminal of the fifth p channel FET 1808 is connected to the source terminal of a sixth p channel FET 1809 whose gate is connected to the Qb output.

The drain terminal of the sixth p channel FET 1809 is connected to the b output.

The a output is further connected to the drain terminal of a first n channel FET 1810 whose gate terminal is connected to the Q output. The source terminal of the first n channel FET 1813 is connected to the drain terminal of a second n channel FET 1811 whose gate terminal is connected to the Db input.

The source terminal of the second n channel FET 1811 is connected to the drain terminal of a third n channel FET 1812 whose gate terminal is supplied with CLK and whose source terminal is connected to ground.

The b output is further connected to the drain terminal of a fourth n channel FET 1813 whose gate terminal is connected to the Qb output. The source terminal of the fourth n channel FET 1813 is connected to the drain terminal of a fifth n channel FET 1814 whose gate terminal is connected to the D input.

The source terminal of the fifth n channel FET 1813 is connected to the drain terminal of a sixth n channel FET 1815 whose gate terminal is supplied with CLK and whose source terminal is connected to ground.

For example, a synchronous non-volatile latch/flip-flop with Q detection may be implemented by replacing the core circuit 501, 602 by the latch 1800.

The truth table of the latch 1800 is given by Table 3.

TABLE 3
Operation mode truth table for synchronous
flip-flop with Q detection

| CLK | D | Q | Q′ | Reset | Set | Phase |
|---|---|---|---|---|---|---|
| ↑ | 0 | 0 | 0 | 0 | 0 | — |
| ↑ | 0 | 1 | 0 | 1 | 0 | HR→LR |
| ↑ | 1 | 0 | 1 | 0 | 1 | LR→HR |
| ↑ | 1 | 1 | 1 | 0 | 0 | — |

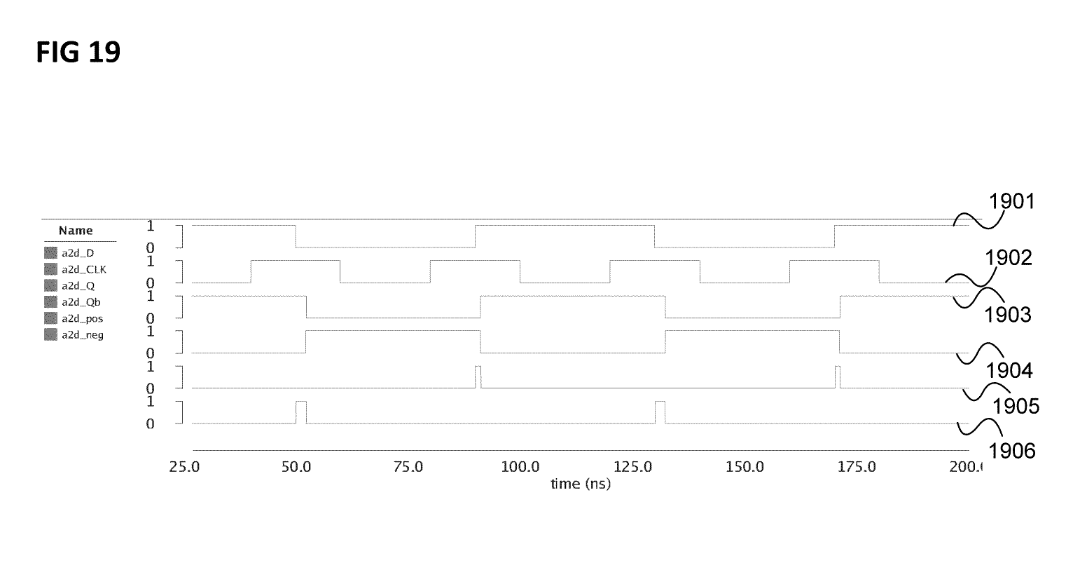

Results of a simulation of the behavior of latch 500 when having latch 1800 as core circuit 501 are given in FIG. 19.

FIG. 19 shows simulation results for a level sensing NVM latch with Q detection.

In FIG. 19, time increases from left to right.

A first graph 1901 shows the behavior of the signal at the D input.

A second graph 1902 shows the behavior of the clock signal.

A third graph 1903 shows the behavior of the Q output.

A fourth graph 1904 shows the behavior of the Qb output.

A fifth graph 1905 shows the behavior of POS=D & !Q.

A sixth graph 1906 shows the behavior of NEG=!D & Q.

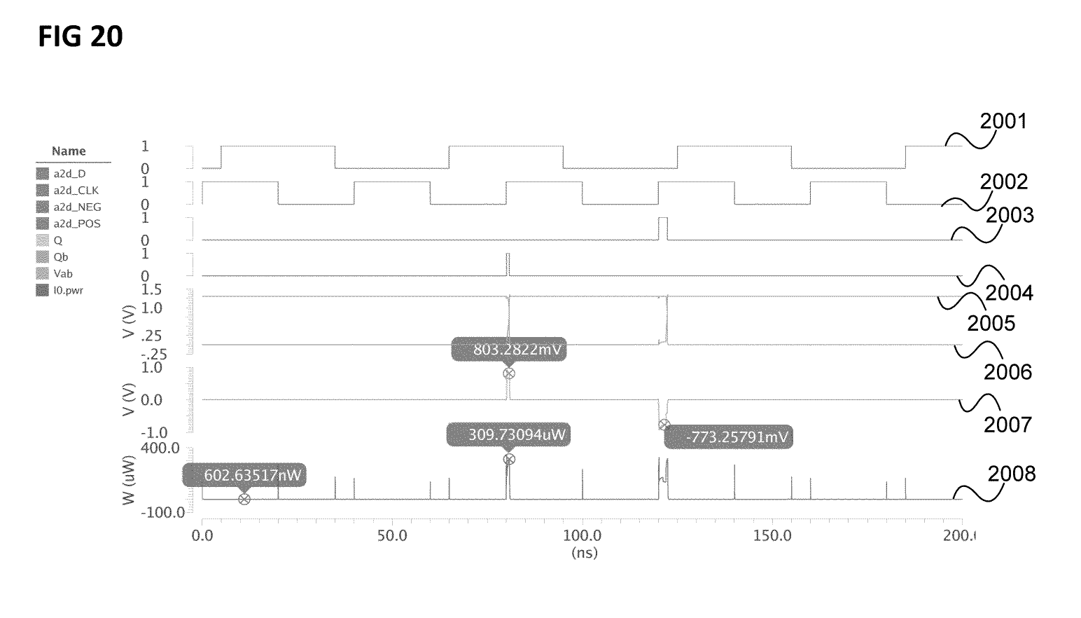

Results of a simulation of the behavior of latch 600 when having latch 1700 as core circuit 602 are given in FIG. 20.

FIG. 20 shows simulation results for a level sensing NVM latch with Q detection.

In FIG. 20, time increases from left to right.

A first graph 2001 shows the behavior of the signal at the D input.

A second graph 2002 shows the behavior of the clock signal.

A third graph 2003 shows the behavior of NEG=!D & Q.

A fourth graph 2004 shows the behavior of POS=D & !Q.

A fifth graph 2005 shows the behavior of the Q output.

A sixth graph 2006 shows the behavior of the Qb output.

A seventh graph 2007 shows the behavior of the voltage between the a output and the b output.

A eighth graph 2008 shows the behavior of the consumed power.

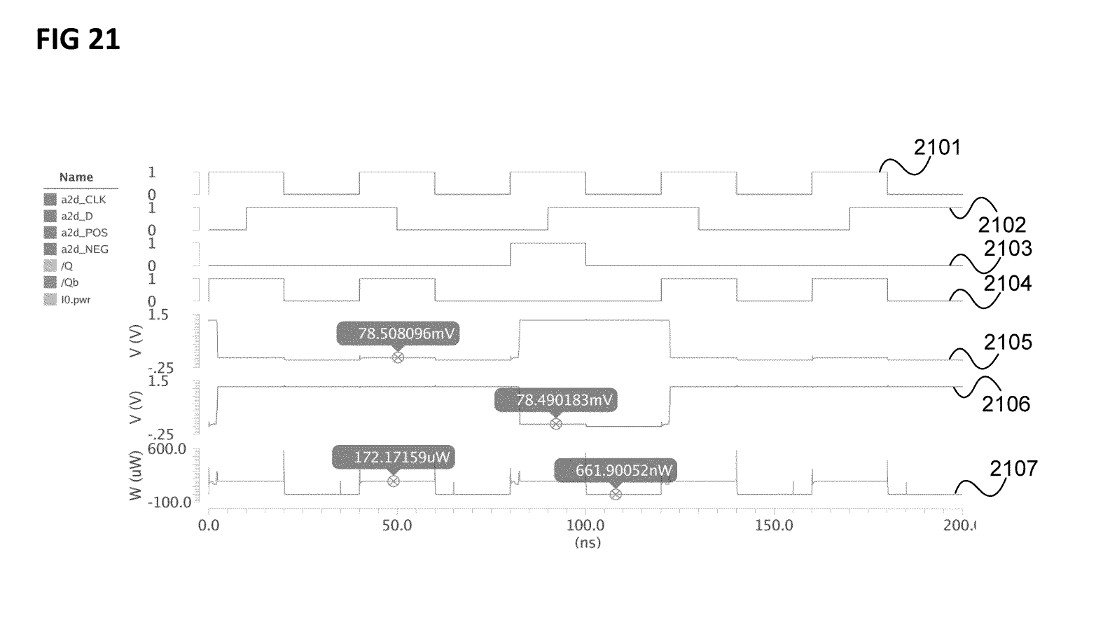

Results of a simulation of the behavior latch 600 when having latch 1800 as core circuit 602 are given in FIG. 21.

FIG. 21 shows simulation results for a level sensing NVM latch with Q detection.

In FIG. 21, time increases from left to right.

A first graph 2101 shows the behavior of the clock signal.

A second graph 2102 shows the behavior at the D input.

A third graph 2103 shows the behavior of POS=D & !Q.

A fourth graph 2104 shows the behavior of NEG=!D & Q.

A fifth graph 2105 shows the behavior of the Q output.

A sixth graph 2106 shows the behavior of the Qb output.

A seventh graph 2107 shows the behavior of the consumed power.

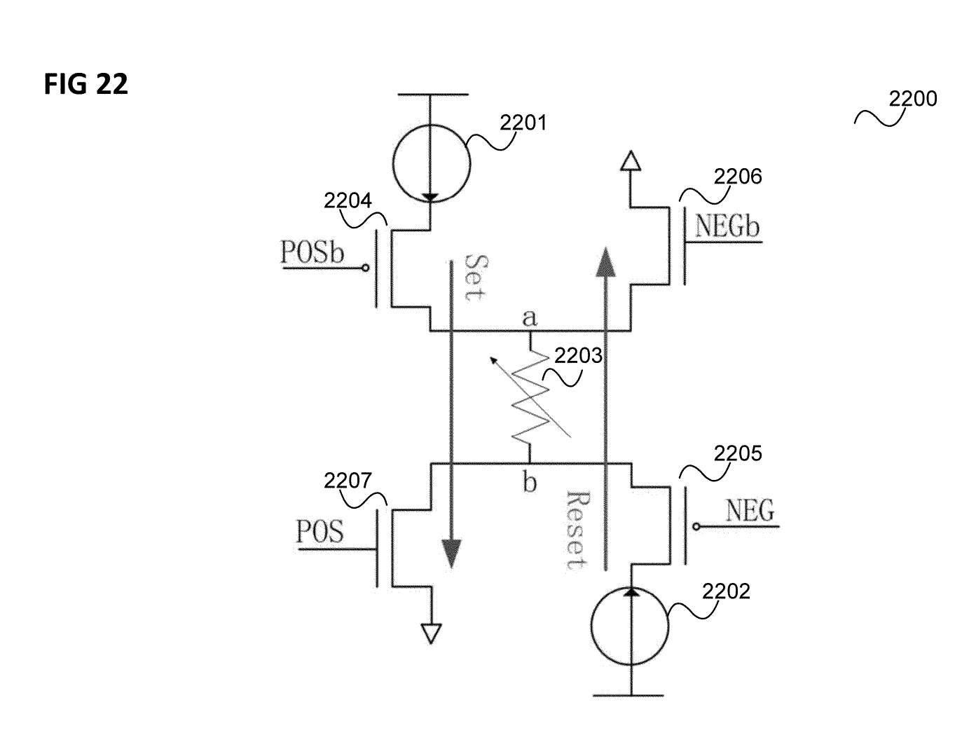

It should be noted that the latches 1500, 1700, 1800 may require a high supply voltage (leading to increased power) and a large transistor size (leading to increased power and reduced speed) in the writing path. This may be addressed by the circuit illustrated in FIG. 22.

FIG. 22 shows a schematic of a bipolar write single cell resistive NVM latch 2200.

The latch 2200 includes a set voltage source 2201, a reset voltage source 2202 and a switchable resistive element 2203 connected between an a output and a b output of the latch 2200.

The set voltage source 2201 is connected between ground and the source terminal of a first p channel field effect transistor (FET) 2204 whose gate is supplied with a POSb signal and whose drain terminal is connected to the a output.

The reset voltage source 2202 is connected between ground and the source terminal of a second p channel FET 2205 whose gate is supplied with a NEG signal.

The drain terminal of the second p channel FET 2205 is connected to the b output.

The a output is further connected to the drain terminal of a first n channel FET 2206 whose gate terminal is supplied with the NEGb signal. The source terminal of the first n channel FET 2206 is connected to ground.

The b output is further connected to the drain terminal of a second n channel FET 2207 whose gate terminal is supplied with the POS signal. The source terminal of the second n channel FET 2207 is connected to ground.

The control signals POS and NEG (and accordingly POSb and NEGb) are generated based on two or more of D, Q and CLK, e.g. according to one of the truth tables as given in tables 1 to 3.

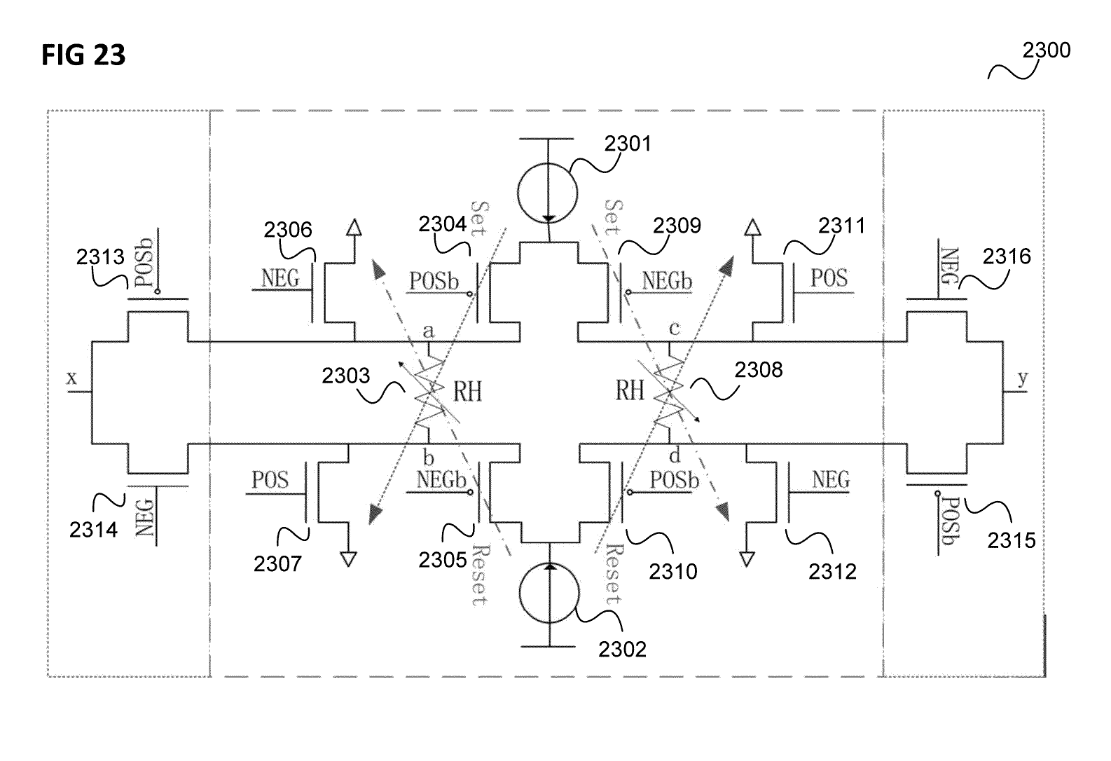

The latches 1500, 1700, 1800 are based on bipolar write single cell structures but other types of structures as described above may be used. For example, a latch based on a bipolar write differential cell structure is explained in the following with reference to FIG. 23.

FIG. 23 shows a schematic of a bipolar differential single cell resistive NVM latch 2300.

The latch 2300 includes a set voltage source 2301, a reset voltage source 2302, a first switchable resistive element 2303 connected between an a node and a b node of the latch 2300 and a second switchable resistive element 2308 connected between a c node and a d node of the latch 2300.

The set voltage source 2301 is connected between ground and the source terminal of a first p channel field effect transistor (FET) 2304 whose gate is supplied with a POSb signal and whose drain terminal is connected to the a node.

The reset voltage source 2302 is connected between ground and the source terminal of a second p channel FET 2305 whose gate is supplied with a NEGb signal.

The drain terminal of the second p channel FET 2305 is connected to the b node.

The a node is further connected to the drain terminal of a first n channel FET 2306 whose gate terminal is supplied with the NEG signal. The source terminal of the first n channel FET 2306 is connected to ground.

The b output is further connected to the drain terminal of a second n channel FET 2307 whose gate terminal is supplied with the POS signal. The source terminal of the second n channel FET 2307 is connected to ground.

Further, the set voltage source 2301 is connected between ground and the source terminal of a third p channel field effect transistor (FET) 2309 whose gate is supplied with the NEGb signal and whose drain terminal is connected to the c node.

The reset voltage source 2302 is connected between ground and the source terminal of a fourth p channel FET 2310 whose gate is supplied with the POSb signal.

The drain terminal of the fourth p channel FET 2310 is connected to the d node.

The c node is further connected to the drain terminal of a third n channel FET 2311 whose gate terminal is supplied with the POS signal. The source terminal of the third n channel FET 2311 is connected to ground.

The d output is further connected to the drain terminal of a fourth n channel FET 2312 whose gate terminal is supplied with the NEG signal. The source terminal of the fourth n channel FET 2312 is connected to ground.

For Q detection NEG=!D & Q and POS=D &!Q.

Without Q detection NEG=!D and POS=D.

The latch 2300 further includes a readout circuit with an x output and a y output which for example correspond to outputs a and b in FIGS. 5 and 6.

The x output is coupled to the a node by means of a fifth p channel FET 2313 whose gate is supplied with the POSb signal and is coupled to the b node by means of a fifth n channel FET 2314 whose gate is supplied with the NEG signal.

The y output is coupled to the d node by means of a sixth p channel FET 2315 whose gate is supplied with the POSb signal and is coupled to the c node by means of a sixth n channel FET 2316 whose gate is supplied with the NEG signal.

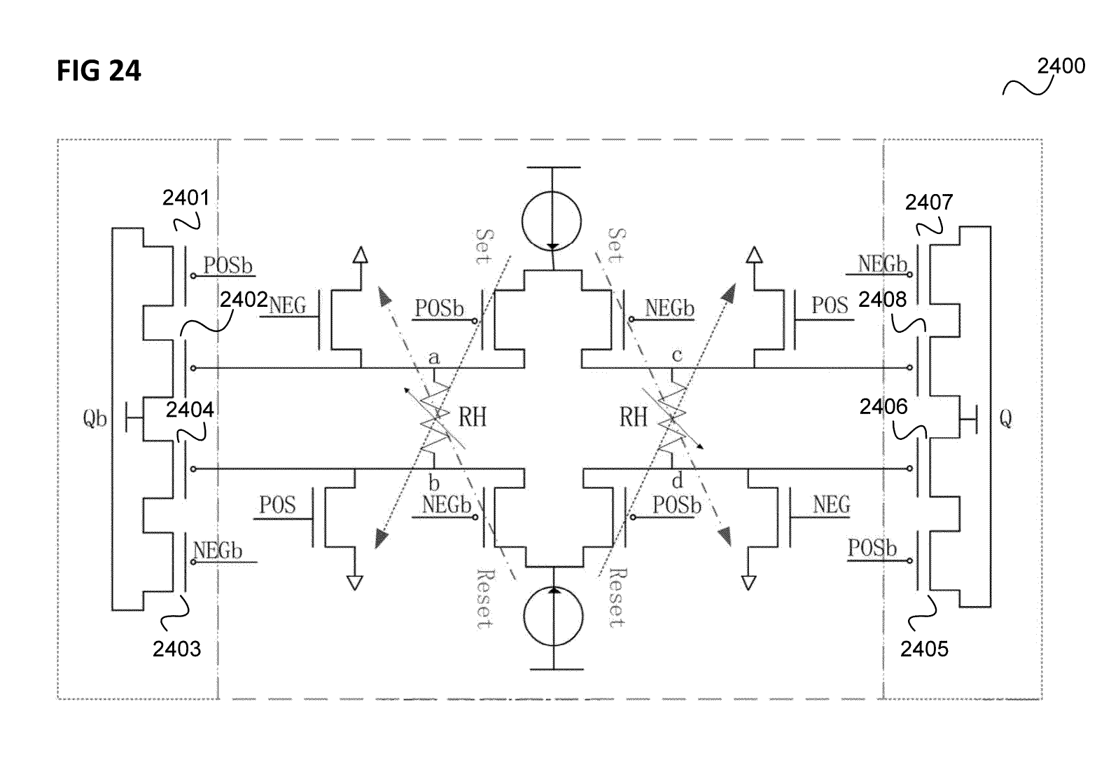

The various latches may also have an improved readout circuit. This is illustrated for latch 2300 in FIG. 24.

FIG. 24 shows a schematic of a bipolar differential single cell resistive NVM latch 2400.

The latch 2400 is similar to the latch 2300 except for the readout circuit.

In the latch 2400, the Qb output is coupled to the source terminal of a first p channel FET 2401 whose gate is supplied with the POSb signal and whose drain is coupled with the source of a second p channel FET 2402. The gate of the second p channel FET 2402 is coupled to the a node and its drain is coupled to ground.

Further, the Qb output is coupled to the source terminal of a third p channel FET 2403 whose gate is supplied with the NEGb signal and whose drain is coupled with the source of a fourth p channel FET 2404. The gate of the fourth p channel FET 2404 is coupled to the b node and its drain is coupled to ground.

The Q output is coupled to the source terminal of a first n channel FET 2405 whose gate is supplied with the POSb signal and whose drain is coupled with the source of a second n channel FET 2406. The gate of the second n channel FET 2406 is coupled to the d node and its drain is coupled to ground.

Further, the Q output is coupled to the source terminal of a third n channel FET 2407 whose gate is supplied with the NEGb signal and whose drain is coupled with the source of a fourth n channel FET 2408. The gate of the fourth n channel FET 2408 is coupled to the c node and its drain is coupled to ground.

The output of latch 2400 is the Q signal and the Qb signal. It should be noted that in the latches 1500, 1700, 1800, 2200, 2300 where there are a and b outputs or a and b nodes (or x and y outputs) these may for example be coupled to a read out circuit to generate Q signal and Qb signal, e.g. to a slave latch as illustrated in FIGS. 5 and 6.

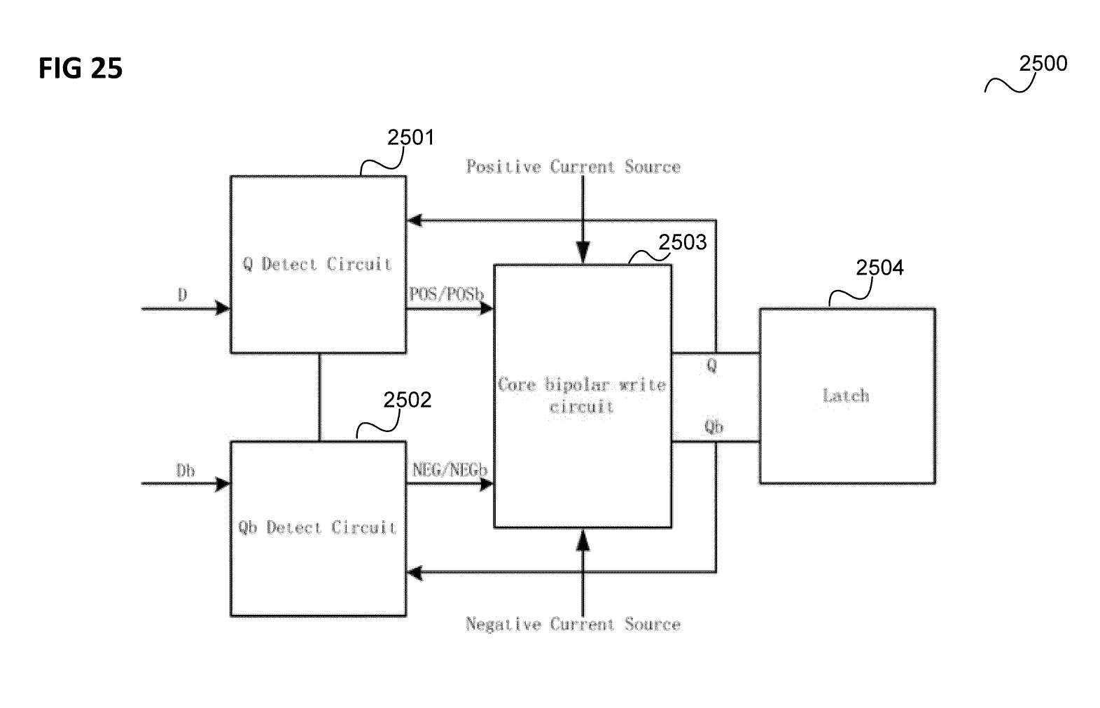

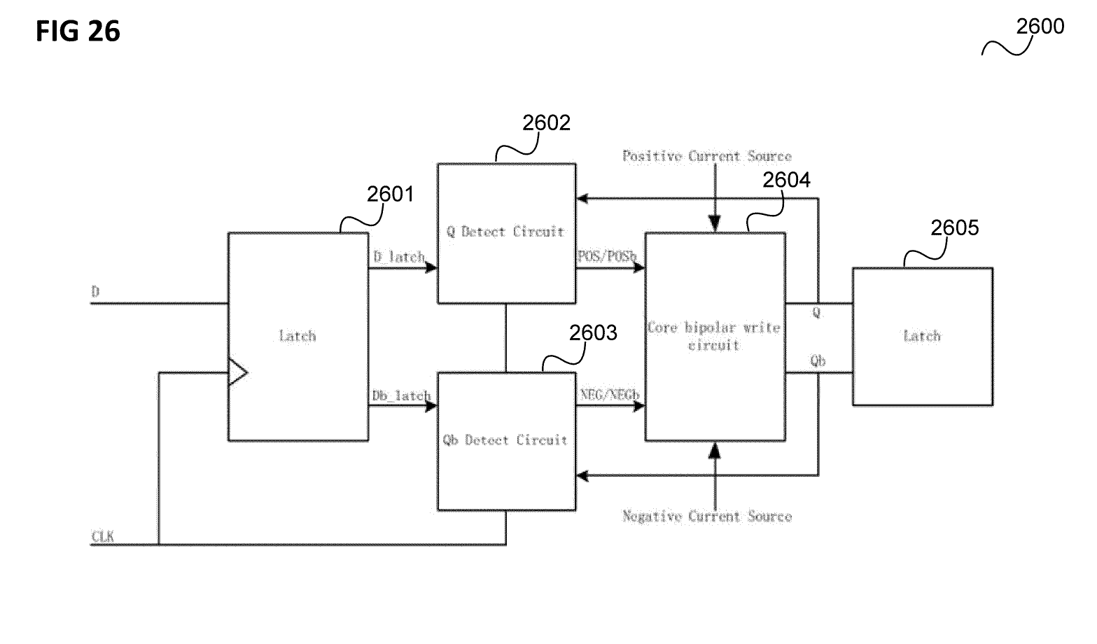

An implementation of latch 500 and flip-flop 600 with Q detection is illustrated in FIGS. 25 and 26.

FIG. 25 shows an asynchronous latch 2500 with Q detection.

The latch 2500 includes a Q detection circuit 2501, a Qb detection circuit 2502, a core bipolar write circuit 2503 and a latch (e.g. slave latch) 2504.

The Q detection circuit 2501 receives the D signal and the Q signal and generates the POS and POSb signal and provides them to the core bipolar write circuit 2503.

The Qb detection circuit 2502 receives the Db signal and the Qb signal and generates the NEG and NEGb signal and provides them to the core bipolar write circuit 2503.

The core bipolar write circuit 2503 generates the Q and Qb signals and supplies them to the latch 2504.

FIG. 26 shows an edge trigger synchronous flip-flop 2600 with Q detection.

The latch 2600 includes a master latch 2601, a Q detection circuit 2602, a Qb detection circuit 2603, a core bipolar write circuit 2604 and a latch (e.g. slave latch) 2605.

The master latch 2601 is clocked by the clock signal CLK.

The master latch 2601 receives the D signal. Its output (whose output signal is referred as D_{latch}) is connected to the Q detection circuit 2602 and its negated output (whose output signal is referred as Db_{latch}) is connected to the Qb detection circuit 2603.

The Q detection circuit 2602 receives the output from the master latch 2601, the CLK signal and the Q signal and generates the POS and POSb signal and provides them to the core bipolar write circuit 2604.

The Qb detection circuit 2603 receives the negated output from the master latch 2601, the CLK signal and the Qb signal and generates the NEG and NEGb signal and provides them to the core bipolar write circuit 2604.

The core bipolar write circuit 2604 generates the Q and Qb signals and supplies them to the latch 2605.

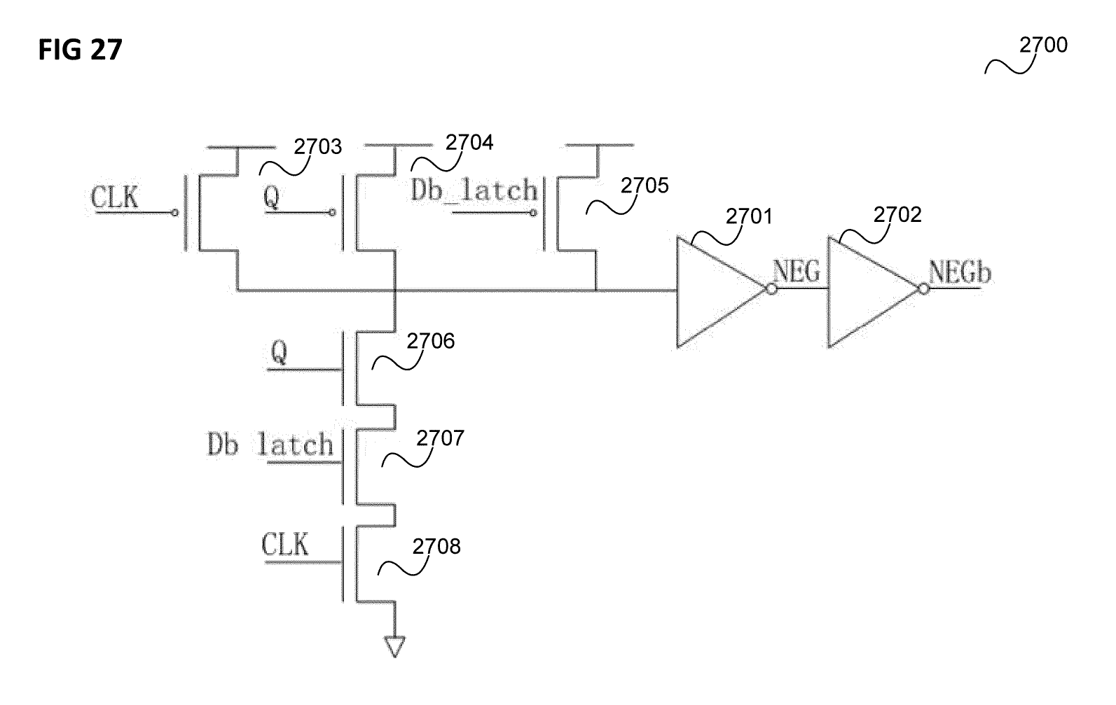

FIG. 27 shows an example for a Q detection circuit 2700 according to an embodiment.

The Q detection circuit 2700 includes a first inverter 2701 whose output is the NEG signal and a second inverter 2702 coupled in series to the first inverter 2701 whose output is the NEGb signal.

A first p channel FET 2703 is coupled between supply and the input of the first inverter 2701. The gate of the first p channel FET 2703 is supplied with the clock signal.

A second p channel FET 2704 is coupled between supply and the input of the first inverter 2702. The gate of the second p channel FET 2704 is supplied with the Q output.

A third p channel FET 2705 is coupled between supply and the input of the third inverter 2703. The gate of the third p channel FET 2705 is supplied with the D_{latch} output.

The input of the first inverter 2701 is further connected to the drain terminal of a first n channel FET 2706 whose gate terminal is supplied with the Q signal and whose source terminal is connected with the drain terminal of a second n channel FET 2707.

The gate terminal of the second n channel FET 2707 is supplied with the Db_{latch} signal and its source terminal is connected with the drain terminal of a third n channel FET 2708.

The gate terminal of the third n channel FET 2708 is supplied with the clock signal and its source terminal is connected to ground.

The Q detection circuit 2700 may be used as Qb detection circuit by supplying Qb instead of Q to the gate terminal of the second p channel FET 2704 and to the gate terminal of the first n channel FET 2706. Then, the output of the first inverter 2701 is the POS signal and the output of the second inverter 2702 is the POSb signal.

The Q detection circuit 2700 (also in its usage as Qb detection circuit) can be included with a bypass function by including a p channel FET between the drain terminal of the second p channel FET 2704 and the input to the first inverter 2701 whose gate terminal is supplied with a bypass signal and including an n channel FET in parallel to the first n channel FET 2706 whose gate terminal is supplied with the bypass signal.

Table 4 shows the operation mode truth table for an edge trigger synchronous flip-flop without Q detection.

TABLE 4
Operation mode truth table for an edge trigger
synchronous flip-flop without Q detection

| CLK | D | Q | Q′ | NEG | POS | Phase |
|---|---|---|---|---|---|---|
| ↑ | 0 | 0 | 0 | 1 | 0 | Set |
| ↑ | 0 | 1 | 0 | 1 | 0 | Set |
| ↑ | 1 | 0 | 1 | 0 | 1 | Reset |
| ↑ | 1 | 1 | 1 | 0 | 1 | Reset |

Table 5 shows the operation mode truth table for an edge trigger synchronous flip-flop with Q detection.

TABLE 5
Operation mode truth table for an edge trigger
synchronous flip-flop wit Q detection

| CLK | D | Q | Q′ | NEG | POS | Phase |
|---|---|---|---|---|---|---|
| ↑ | 0 | 0 | 0 | 0 | 0 | — |
| ↑ | 0 | 1 | 0 | 1 | 0 | Set |
| ↑ | 1 | 0 | 1 | 0 | 1 | Reset |
| ↑ | 1 | 1 | 1 | 0 | 0 | — |

It should be noted that the state of the core circuit may be different from the state of the slave latch during recovery. If the D input is always the same as the Q output until the flip-flop is powered off the state will not be written into the NVM cell in case of Q detection. To overcome this issue, according to one embodiment, it is ensured the state of core circuit and the slave latch are synchronized after initialization (set/reset) or after recovery. For this, for example, Q detection is disabled during an initialization and a restore phase. The truth tables for recovery mode with Q detector turned on/off are given in Table 6 and Table 7.

TABLE 6
Recovery mode truth table for synchronous
latch/flip-flop without Q detection

| CLK | D | Q | State | Q′ | NEG | POS |
|---|---|---|---|---|---|---|
| ↑ | 0 | X | LR | 0 | 1 | 0 |
| ↑ | 0 | X | HR | 1 | 1 | 0 |
| ↑ | 1 | X | LR | 0 | 0 | 1 |
| ↑ | 1 | X | HR | 1 | 0 | 1 |

TABLE 7
Recovery mode truth table for synchronous
latch/flip-flop with Q detection

| CLK | D | Q | State | Q′ | NEG | POS |
|---|---|---|---|---|---|---|
| ↑ | 0 | 0 | X | 0 | 0 | 0 |
| ↑ | 0 | 1 | LR | 0 | 1 | 0 |
| ↑ | 0 | 1 | HR | 1 | 1 | 0 |
| ↑ | 1 | 0 | LR | 0 | 0 | 1 |
| ↑ | 1 | 0 | HR | 1 | 0 | 1 |
| ↑ | 1 | 1 | X | 1 | 0 | 0 |

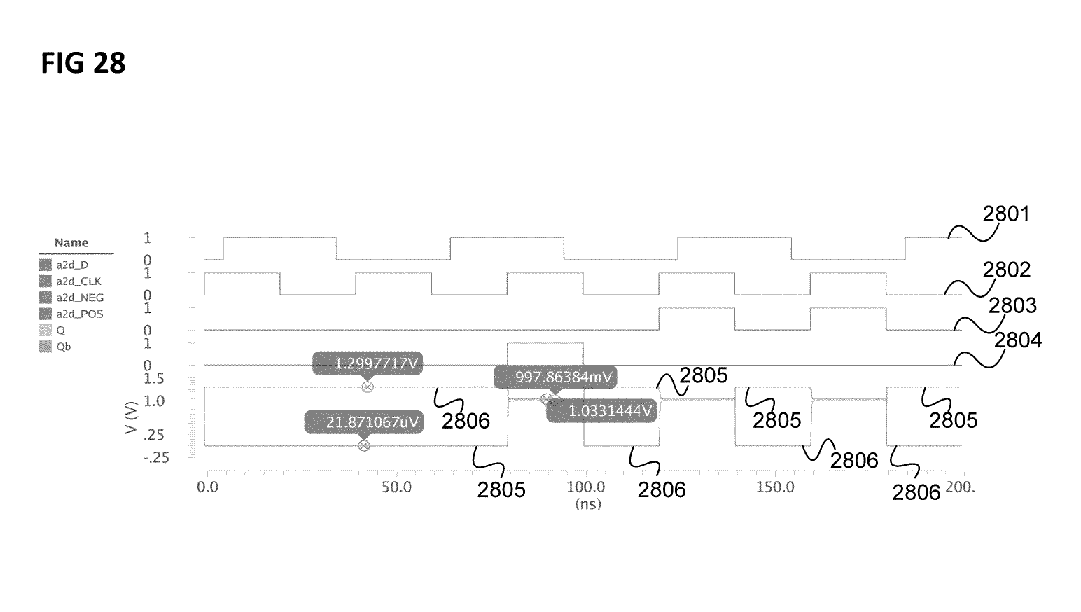

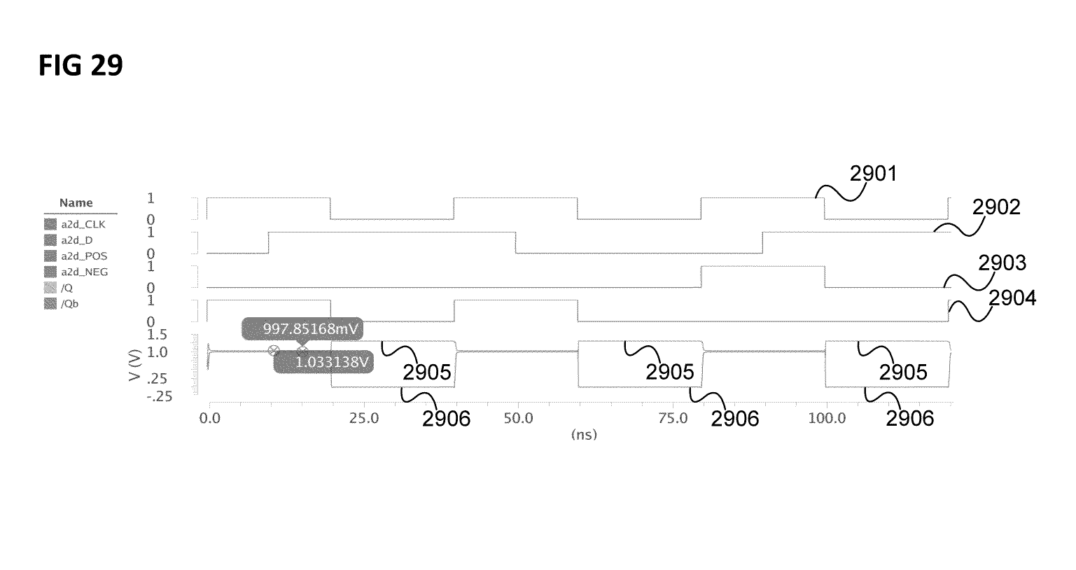

Simulation results during recovery are shown in FIGS. 28 and 29.

FIG. 28 shows simulation results for the recovery with Q detection.

In FIG. 28, time increases from left to right.

A first graph 2801 shows the behavior of the signal at the D input.

A second graph 2802 shows the clock signal.

A third graph 2803 shows the behavior of NEG=!D & Q.

A fourth graph 2804 shows the behavior of POS=D & !Q.

A fifth graph 2805 shows the behavior of Q.

A sixth graph 2806 shows the behavior of Qb.

FIG. 29 shows simulation results for the recovery without Q detection (e.g. with the bypass signal being set to high during recovery phase).

In FIG. 29, time increases from left to right.

A first graph 2901 shows the clock signal.

A second graph 2902 shows the behavior of the signal at the D input.

A third graph 2903 shows the behavior of POS=D & !Q.

A fourth graph 2904 shows the behavior of NEG=!D & Q.

A fifth graph 2905 shows the behavior of Q.

A sixth graph 2906 shows the behavior of Qb.

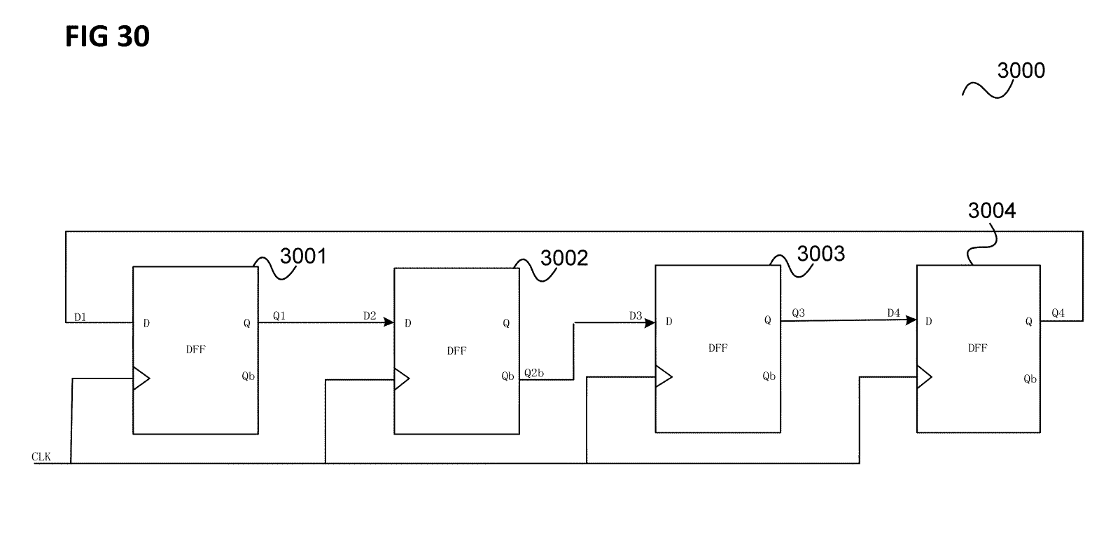

The functionality of the non-volatile flip-flops may for example be verified by means of a test circuit as illustrated in FIG. 30.

FIG. 30 shows a test circuit 3000.

The test circuit 3000 includes four non-volatile flip-flops 3001 to 3004 which are connected in a loop. Specifically, the output Qb of the fourth flip-flop 3004 is the input D of the first flip-flop 3001 and the input D of the other three flip-flops 3002, 3003, 3004 is the Q output of the preceding flip-flop.

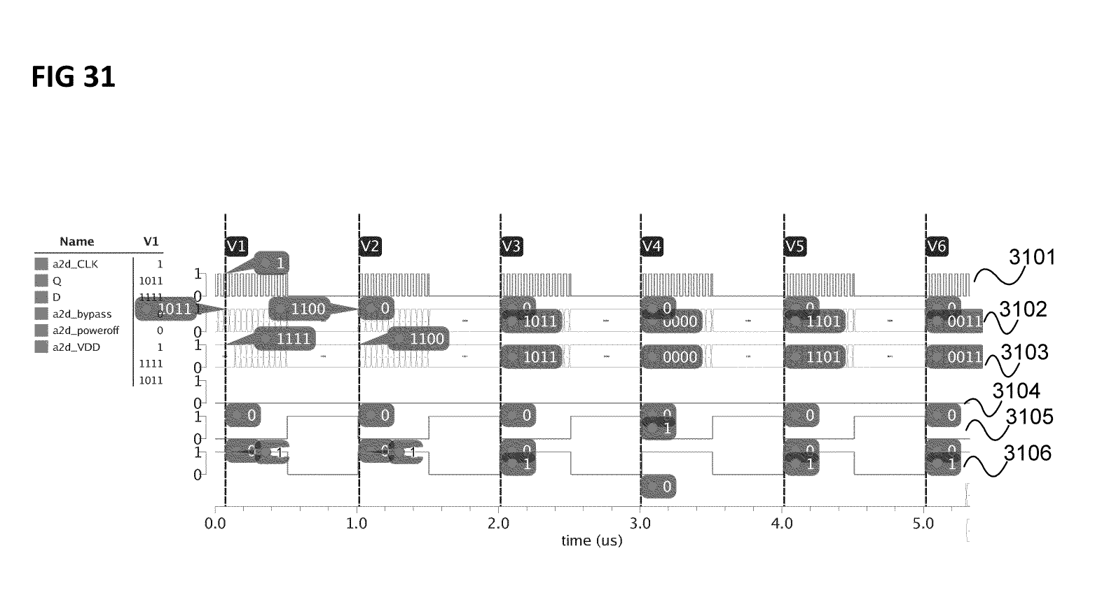

FIG. 31 shows simulation results for the case that Q detection is always turned on.

In FIG. 31, time increases from left to right.

A first graph 3101 shows the clock signal.

A second graph 3102 shows the behavior of the Q outputs of the flip-flops 3001 to 3004.

A third graph 3103 shows the behavior of the states of the flip-flops 3001 to 3004.

A fourth graph 3104 shows the behavior of bypass signals of the flip-flops 3001 to 3004.

A fifth graph 3105 shows the state of a power off signal (i.e. a signal indicating whether power is switched off).

A sixth graph 3106 shows the state of VDD.

As can be seen from FIG. 31 at the initial stage the slave latches are not synchronized to the core circuits' states.

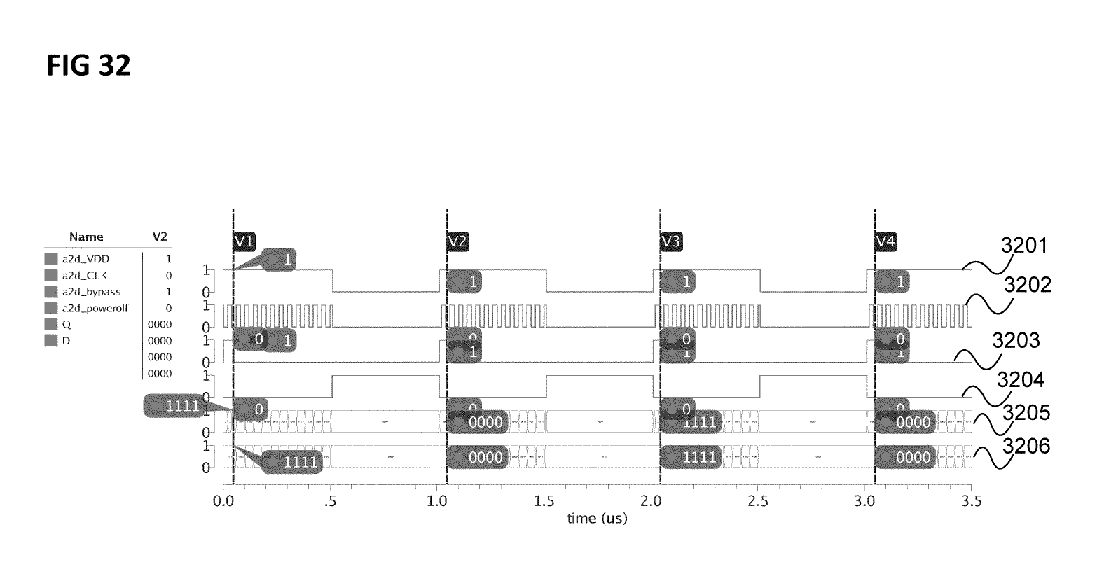

Another simulation to verify the initialization stage and restore stage with Q detection disabled is illustrated in FIG. 32.

FIG. 32 shows simulation results for the case that Q detection is disabled during recovery.

In FIG. 32, time increases from left to right.

A first graph 3201 shows the state of VDD.

A second graph 3202 shows the clock signal.

A third graph 3203 shows the behavior of bypass signals of the flip-flops 3001 to 3004.

A fourth graph 3204 shows the behavior of the power off signal.

A fifth graph 3205 shows the behavior of the Q output of the flip-flops 3001 to 3004.

A sixth graph 3206 shows the behavior of the states of the flip-flops 3001 to 3004.

Due to Q detection being turned off the output of the slave latch is synchronized to core circuit state at both initialization stage and recovery (restore) stage. Q detection being disabled is more reliable during recovery at the cost of an additional control signal (e.g. the bypass signal).

For a comparison of power consumption let updating NVM cells in the non-volatile flip-flop require energy J1, restore require energy J2 and a conventional retention flip-flop having the equivalent leakage power P3 (including the combinational logic and decoupling capacitor leakage power) and the percentage of registers need to retain the states be K. Let the average operation frequency of the non-volatile flip-flop be f and the operation time be Ton. Then the minimum standby time is

Toff=(Ton*f*J1+J2)*K/P3≈Ton*f*J1*K/P3

It also can be written as

Duty cycle=Ton/(Ton+Toff)=P3/(P3+f*J1*K)

Therefore, when the on duty cycle of the non-volatile flip-flop described above (i.e. form 1) is smaller than P3/(P3+f*J1*K) the non-volatile flip-flop described above reduces the standby power consumption.

In the nvFF as described above, the state of the NVM cell (or NVM cells) is updated every clock cycle. However, before the power consumption of changing the state of the NVM cell has been reduced lower than changing the state of the register, the dynamic power consumption of the nvFF described above may be increased without proper methodologies have been applied. Moreover, to update the state of a NVM cell typically requires a few nanoseconds which is much slower than turning on/off a transistor. Hence the operation speed may be limited by the NVM cell updating speed. In the systems which may not be necessary to record the states of the registers every clock cycle, it is sufficient to retain the information of the registers before they have been powered off. In other words, it consumes only retention power and restoration power during the power modes transition (from sleep mode to active mode or from active mode to sleep mode). Therefore, the power consumption could be reduced. Further, in case the NVM cell is only updated once before the system enters into SLEEP mode the effect of the NVM cell update on the operation speed of the nvFF can be minimized.

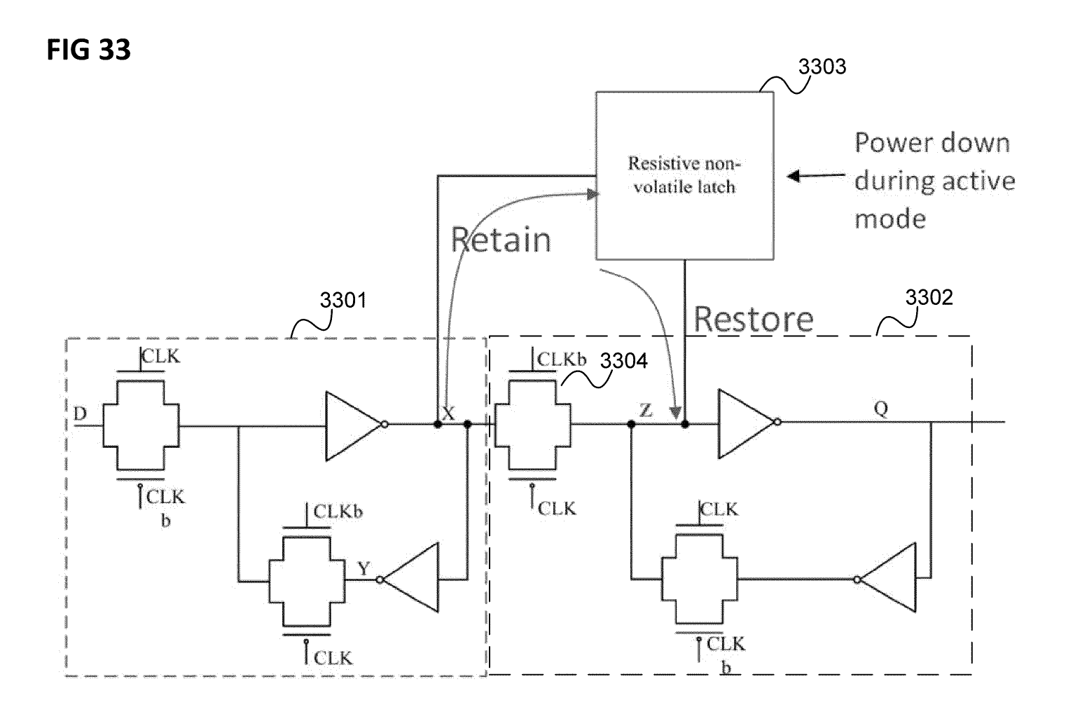

FIG. 33 shows a block diagram of a non-volatile shadow latch based retention register 3300 according to one embodiment.

The retention register 3300 includes a master latch 3301, a slave latch 3302 and a resistive non-volatile latch 3303.

The non-volatile latch 3303 can be seen to replace the shadow latch 203 of FIG. 2.

The output of the master latch 3301 (denoted X) is connected to the input of the resistive non-volatile latch 3303. The resistive non-volatile latch 3303 is for example implemented similar to a core circuit 501, 602, e.g. according to one of FIGS. 7 to 10.

The output of the resistive non-volatile latch 3303 is connected to the input of the slave latch 3302 wherein it bypasses the clocked input transmission gate 3304 of the slave latch.

The non-volatile shadow latch based retention register 3300 for example has two operation mode, namely active mode and standby (or sleep) mode. For example, the retention register 3300 only has these two modes to reduce complexity of the power management block.

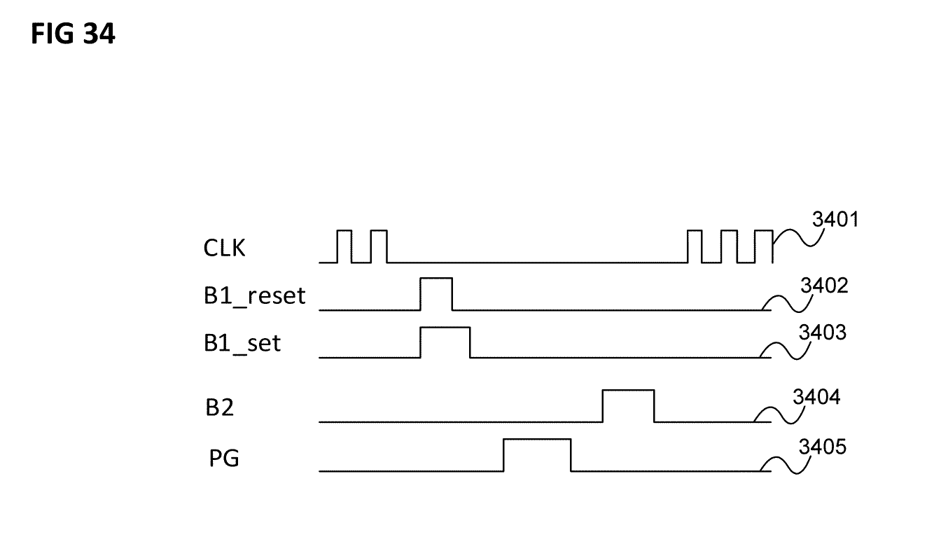

The non-volatile latch 3303 is powered down during active mode. When the system (including the register) receives a sleep command (i.e. the command to enter sleep mode), the non-volatile latch 3303 is powered on first. Then the clock signal is disabled to prevent it from disturbing the states when updating the NVM cell or cells of the non-volatile latch 3303. An example for a signal flow is illustrated in FIG. 34.

FIG. 34 shows the read/write waveforms for the resistive non-volatile latch 3303.

In FIG. 34, time increases from left to right.

A first graph 3401 shows clock signal.

A second graph 3402 shows a B1ᵣₑₛₑₜ signal.

A third graph 3403 shows a B1ₛₑₜ signal.

A fourth graph 3404 shows a B2 signal.

A fifth graph 3405 shows a PG signal.

B1 is the write enable signal, which is used to control the voltage or current source to program NVM cell. In the example of FIG. 34, e.g. for the case that set and reset of a NVM cell requires different pulse widths, B1 is separated into the two control signals B1ₛₑₜ and B1ᵣₑₛₑₜ. These signals are for example used for switch control similar to the D signal and the !D signal in FIGS. 7 to 10 and only one of them is activated depending on the input to the resistive non-volatile latch 3003.

Once B1 is high, the X output of the master latch 3301 or the Y output of the master latch 3301 (i.e. the negated X output) enable the SET or the RESET path to program the NVM cell (or NVM cells) of the resistive non-volatile latch 3303. The signal PG then goes to 1 to indicate that all NVM cells have been programmed successfully.

Another phase is from SLEEP mode to ACTIVE mode. Once a monitor block of the register 3300 receives an ACTIVE signal all components of the register 3300 are powered on. To avoid any disturbance during reading, the clock signal is still pulled to ground. Then the read enable signal B2 goes to 1 to sense the data from the resistive non-volatile latch 3303 to the register (i.e. slave latch 3302), e.g. to trigger that non-volatile latch 3303 outputs its state (e.g. via a voltage sense amplifier in FIGS. 7 to 10). The output node of the non-volatile resistive latch 3303 may be connected to the x output of the master latch 3301, the y output of the master latch 3303 or, as shown in FIG. 33, to the node z (output node of transmission gate 3304) which depends on the detail design of the non-volatile latch 3303.

The resistive non-volatile latch 3303 may use a NVM cell that requires unipolar write or a NVM cell that requires bipolar write. Further, the resistive non-volatile latch 3303 may use a single NVM cell (i.e. a single switchable resistance element) to store information to save chip area, or a differential cell structure to enhance the read reliability.

Accordingly, all four types of non-volatile latches as shown in FIGS. 7 to 10—unipolar write signal cell, unipolar write differential cells, bipolar write signal cell and bipolar write differential cell—may be used. Single cell structures have fewer transistors but should have a reference signal to determine the states of the NVM cells during sensing. The sense amplifier in the shadow latch may be reused by the slave 3302 latch to save chip area.

The bipolar write differential cells structure typically has more transistors than the other three structures, i.e. the other three types of non-volatile latches.

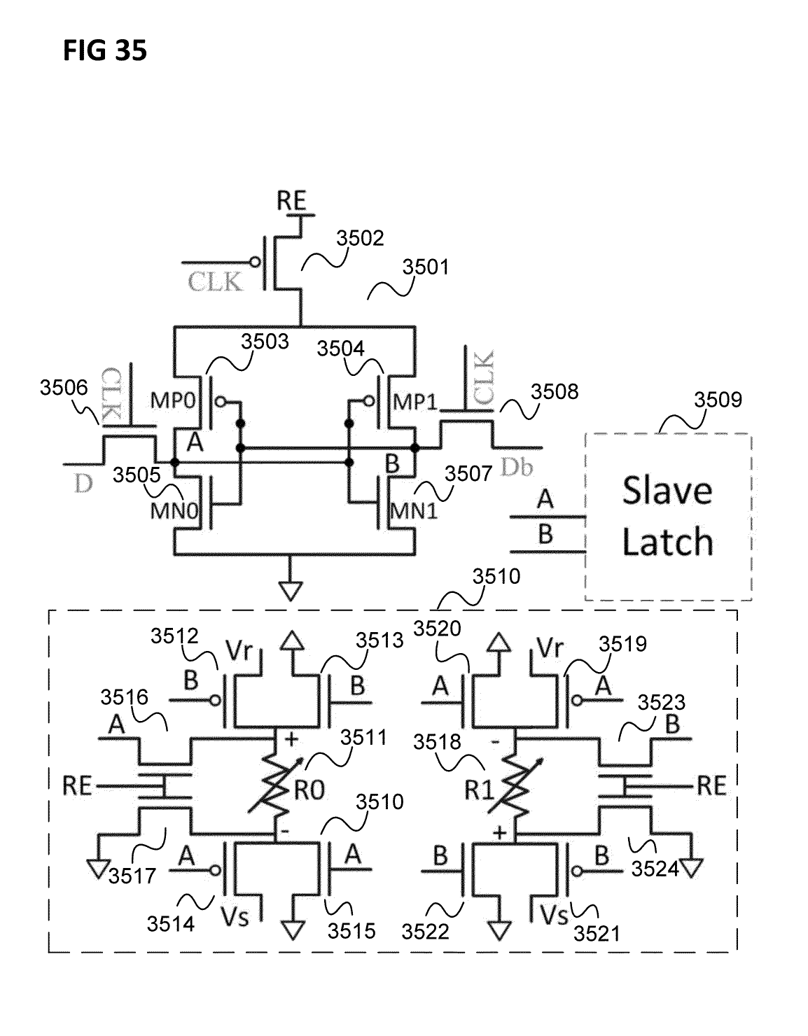

An example is shown in FIG. 35 to evaluate the number of transistors and the feasibility.

FIG. 35 shows a master latch 3501, a slave latch 3509 and a resistive non-volatile latch 3510.

The master latch 3501 for example corresponds to master latch 3301 and is an SRAM-like structure in this example. It is for example used as the sense amplifier during restoration.

The master latch includes a first p channel FET 3502 whose source is supplied with the read enable signal, whose gate terminal is supplied with the clock signal and whose drain terminal is connected to the source terminal of a second p channel FET 3503 and a third p channel FET 3504.

The drain terminal of the second p channel FET 3503 is connected to the drain of a first n channel FET 3505 and to the drain of a second n channel FET 3506.

The source of the first n channel FET 3505 is connected to ground and its gate is connected to the gate of the second p channel FET 3503.

The source of the second n channel FET 3506 is connected to the D input and its gate is supplied with the clock signal.

The drain terminal of the third p channel FET 3504 is connected to the drain of a third n channel FET 3507 and to the drain of a fourth n channel FET 3508.

The source of the third n channel FET 3507 is connected to ground and its gate is connected to the gate of the third p channel FET 3504.

The source of the fourth n channel FET 3508 is connected to the Db input and its gate is supplied with the clock signal.

The drain of the second p channel FET 3503 is referred to as node A which is connected to the gate terminal of the third p channel FET 3504.

The drain of the third p channel FET 3504 is referred to as node B which is connected to the gate terminal of the second p channel FET 3503.

The state of node A is the state of the master latch 3501 and the state of node B is the negated state of the master latch 3501.

Slave latch 3509 is simply represented as a block to show that its inputs are connected to node A and to node B.

The resistive non-volatile latch 3510 is a non-volatile shadow latch with read/write circuit. It includes a first switchable resistive element 3511 which is connected, on a first side, with the drain terminal of a fourth p channel FET 3512 and the drain terminal of a fifth n channel FET 3513 and, on a second side, with the drain terminal of a fifth p channel FET 3514 and the drain terminal of a sixth n channel FET 3515.

The gate terminal of the fourth p channel FET 3512 is connected to the B node and its source is supplied with the reset voltage Vr.

The gate terminal of the fifth n channel FET 3513 is connected to the B node and its source is connected to ground.

The gate terminal of the fifth p channel FET 3514 is connected to the A node and its source is supplied with the set voltage Vs.

The gate terminal of the sixth n channel FET 3515 is connected to the A node and its source is connected to ground.

The first side of the first switchable resistive element 3511 is further connected to the A node by a seventh n channel FET 3516 whose gate terminal is supplied with the RE signal.

The second side of the first switchable resistive element 3511 is further connected to ground by an eighth n channel FET 3517 whose gate terminal is supplied with the RE signal.

Further, the resistive non-volatile latch includes a second switchable resistive element 3518 which is connected, on a first side, with the drain terminal of a sixth p channel FET 3519 and the drain terminal of a ninth n channel FET 3520 and, on a second side, with the drain terminal of a seventh p channel FET 3521 and the drain terminal of a tenth n channel FET 3522.

The gate terminal of the sixth p channel FET 3519 is connected to the A node and its source is supplied with the reset voltage Vr.

The gate terminal of the ninth n channel FET 3520 is connected to the A node and its source is connected to ground.

The gate terminal of the seventh p channel FET 3521 is connected to the B node and its source is supplied with the set voltage Vs.

The gate terminal of the tenth n channel FET 3522 is connected to the B node and its source is connected to ground.

The first side of the second switchable resistive element 3518 is further connected to the B node by an eleventh n channel FET 3523 whose gate terminal is supplied with the RE signal.

The second side of the second switchable resistive element 3518 is further connected to ground by a twelfth n channel FET 3524 whose gate terminal is supplied with the RE signal.

The slave latch 3509 may be a normal latch as in a conventional register. In normal operation mode (ACTIVE mode), the voltage source Vr and Vs may both be set to ground and RE (e.g. corresponding to B2 signal in FIG. 24) signal is low. Therefore, there is no current through the switchable resistive elements 3511, 3518. In the transition period from ACTIVE mode to SLEEP mode, RE=0, CLK=0 and a SET pulse and RESET pulse are provided as Vr and Vs, respectively, e.g. in response to a write enable (WE) signal.

According to the states of A and B different write operations are performed on the switchable resistive elements 3511, 3518. For example, if A=1, B=0, then the first switchable resistive elements 3511 is reset and the second switchable resistive element 3518 is set. In the transition period from SLEEP mode to ACTIVE mode, Vr=Vs=0, CLK=0 and RE goes to 1 to sense the information of R0 and R1 to nodes A and B. When RE goes to low, the states of A and B are latched.

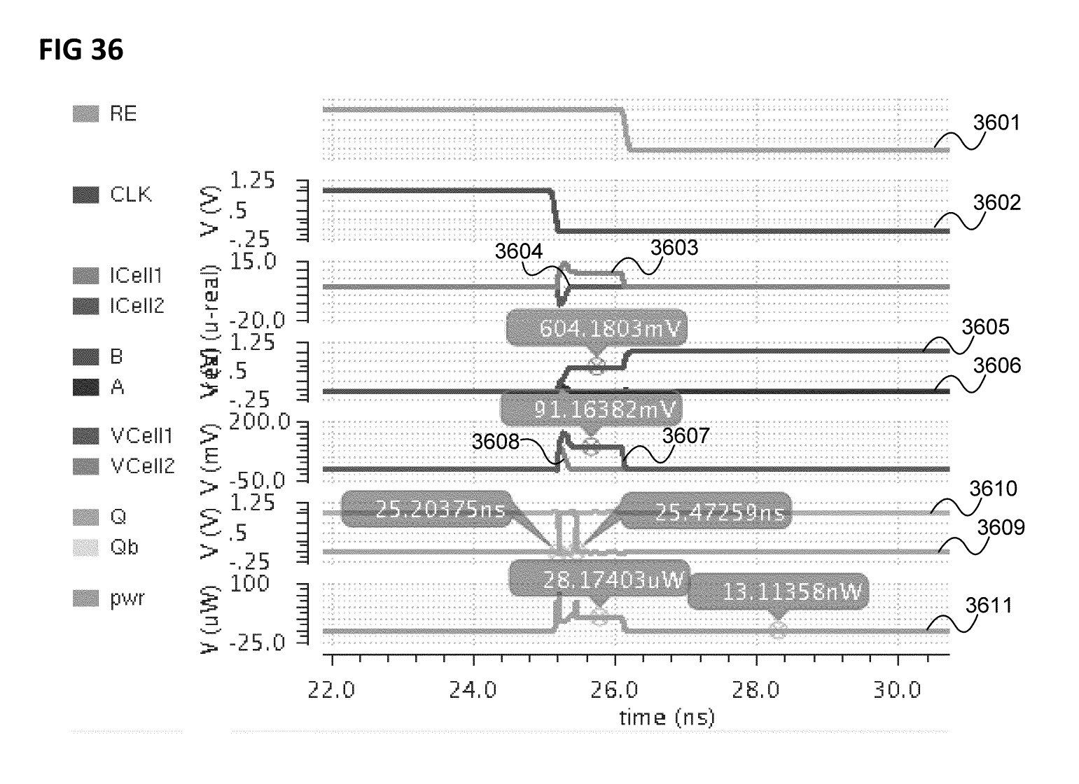

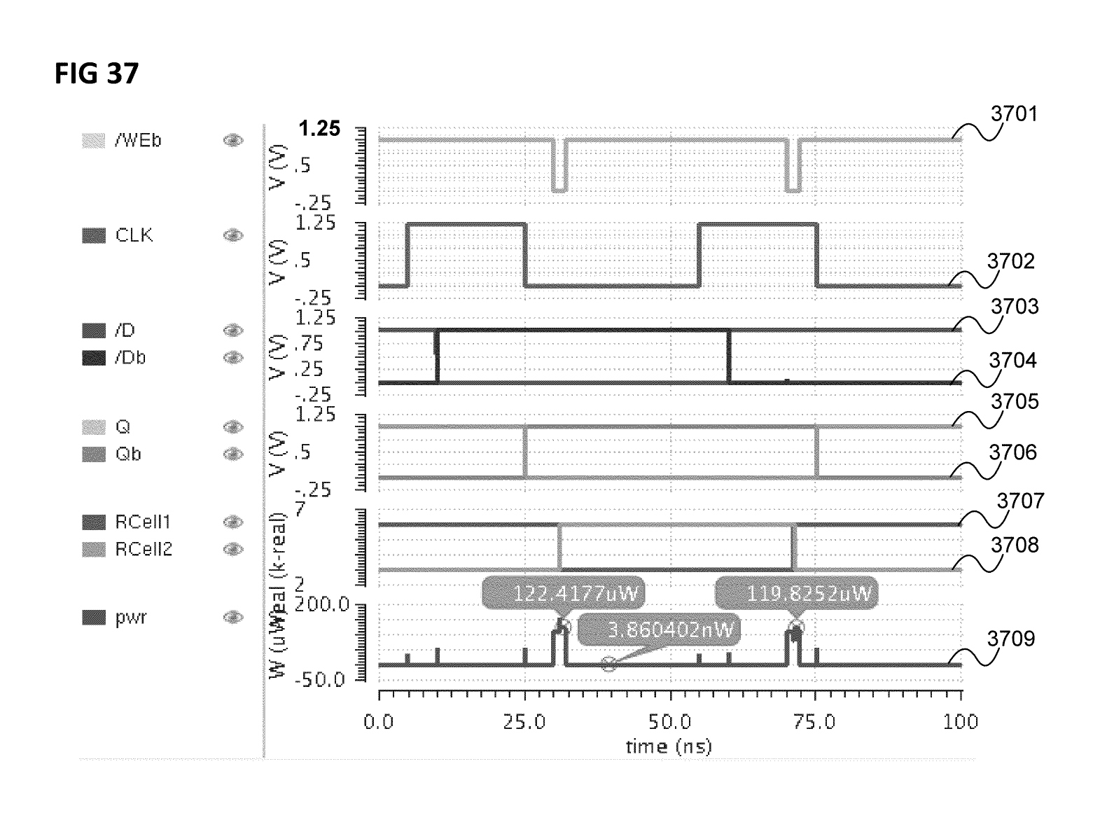

Results of the simulation of the reading from the resistive non-volatile latch 3303 and the writing to the resistive non-volatile latch 3303 are illustrated in FIGS. 36 and 37.

The simulation is based on a 45 nm generic pdk (process design kit) and an STT-MRAM model: 65 nm, Jc0=3e+10, Rp=3K, TMR=100%.

FIG. 36 shows reading simulation results of a retention register with a bipolar write differential cells resistive NVM shadow latch.

In FIG. 36, time increases from left to right.

A first graph 3601 shows the read enable signal.

A second graph 3602 shows the clock signal.

A third graph 3603 shows the current through the first resistive element 3511.

A fourth graph 3604 shows the current through the second resistive element 3518.

A fifth graph 3605 shows the voltage of the B node.

A sixth graph 3606 shows the voltage of the A node.

A seventh graph 3607 shows the voltage at the first resistive element 3511.

An eighth graph 3608 shows the voltage at the second resistive element 3518.

A ninth graph 3609 shows the Q signal.

A tenth graph 3610 shows the Qb signal.

An eleventh graph 3611 shows the power consumption.

The reading speed can reach as fast as 270 ps and the reading power is only 28 uW. When RE is disabled, there is no DC (direct current) current path. Therefore, the circuit has very low reading power consumption. The reading voltage on the NVM cell is only 91 mV, which should be much smaller than writing voltage. Hence, the read disturbance is very small.

FIG. 37 shows the writing simulation results of retention register with the bipolar write differential cells resistive NVM shadow latch.

In FIG. 37, time increases from left to right.

A first graph 3701 shows the negated write enable signal Web.

A second graph 3702 shows the clock signal.

A third graph 3703 shows the D signal.

A fourth graph 3704 shows the Db signal.

A fifth graph 3705 shows the Q signal.

A sixth graph 3706 shows the Qb signal.

A seventh graph 3707 shows the resistance of the first switchable resistive cell.

An eighth graph 3708 shows the resistance of the second switchable resistive cell.

A ninth graph 3709 shows the power consumption.

The writing operation is controlled by WEb (B1ₛₑₜ and B1ᵣₑₛₑₜ). The writing speed is around 1 ns and writing power is about 120 uW is this example.

The non-volatile flip-flop as described above allows

Scaling (Scaling, lower then write voltage), normal operation speed (no need to update NVM cells every clock cycle, no current goes through NVM cells during operation), dynamic power (no need to update every clock cycle, fast operation speed) and may be implemented with low area requirements (e.g. with 27 transistors and two switchable resistive elements 27T+2R).

A performance comparison between the non-volatile flip-flop as described above and conventional flip-flops is given in table 8.

TABLE 8
Performance comparison based on estimations

| | | | Normal | |
|---|---|---|---|---|
| | | | Operation | |
| | | | Speed | Dynamic |
| | Number | Estimated | (Setup time + | Power |
| | of | Area | hold | per |
| Structure | Devices | (Normalized) | time) | cycle |
| CMOS DFF | 25T | 1 | ~100 ps | ~2 fJ |
| Conventional | 30T + 2R | 1.68 | A few ns | ~0.3 pJ |
| spin-MTJ based | | | (MTJ read | |
| flip-flop | | | speed + | |
| | | | write speed + | |
| | | | latch | |
| | | | setup time + | |
| | | | hold | |
| | | | time) | |
| Conventional | 32T + 2R | 1.76 | ~1 ns (MTJ | ~10 fJ |
| magnetic flip- | | | read speed + | |
| flop | | | latch | |
| | | | setup time + | |
| | | | hold | |
| | | | time) | |
| Described flip- | 27T + 2R | 1.64 | ~100 ps | ~2 fJ |
| flop | | | | |

Let updating NVM cells in the nvFF require energy J1, restore require energy J2 and a conventional retention flip-flop have the equivalent leakage power P3 (including the combinational logic and decoupling capacitor leakage power) and the percentage of registers need to retain the states be K. Then the minimum standby time is

Toff=(J1+J2)*K/P3

Hence, the non-volatile flip-flop described above (i.e. form 1) is only dependent on the standby time rather than on/off duty cycle. When the off time is longer than (J1+J2)*K/P3, nvFF (of form 2) has the advantage to reduce the standby power consumption.

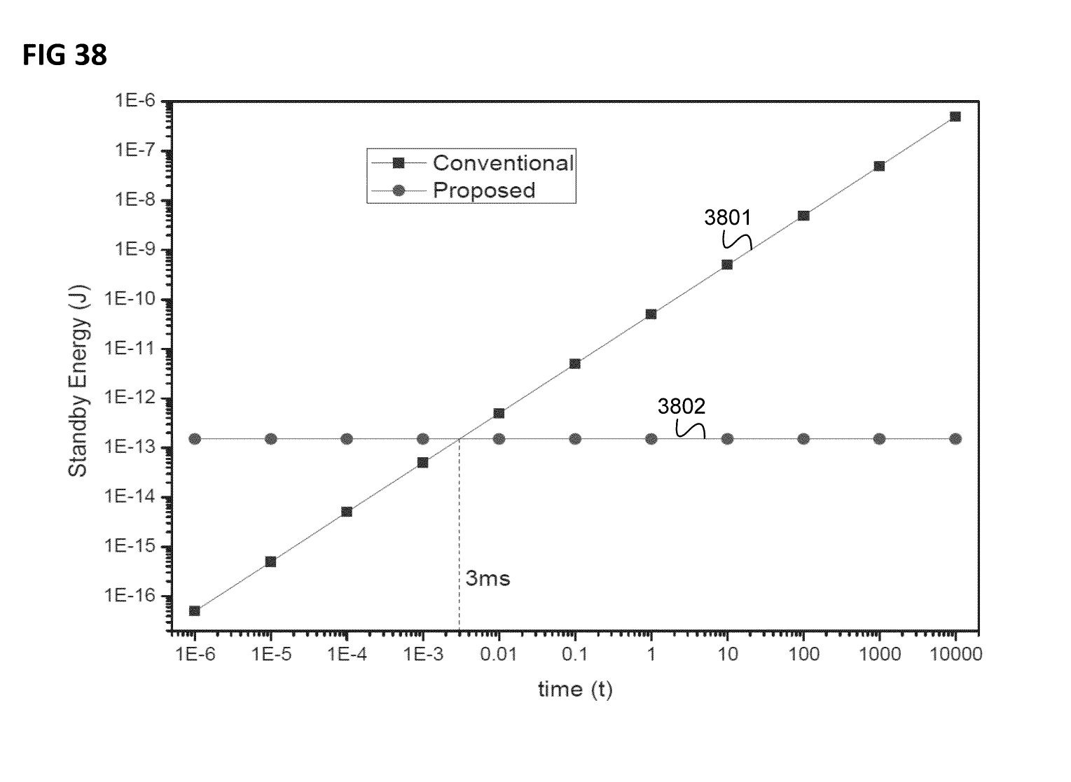

FIG. 38 shows a leakage comparison between a nvFF (of form 2) according to an embodiment and a conventional retention flip-flop.

A first graph 3801 shows the dependency of standby energy from time for a conventional flip-flop and a second graph 3802 shows the dependency of standby energy from time for a flip-flop (of form 2) provided according to an embodiment.

As can be seen, the provided nvFF has a power advantage when the standby time is longer than 3 ms. For example, when standby time is 1 s, the provided nvFF allows saving 1000 times leakage power. Moreover, the comparison of FIG. 38 is based on single cell comparison. In practical, not only register consumes leakage power, other combination logic, decoupling capacitor also consumes large leakage power. And only a few percentage of registers have to retain the information (i.e., only 10% registers need to be non-volatile). Therefore, the equivalent leakage power consumption in practical system could be reduced K times. For example, if K=20, the crossing time will shift from 3 ms to around 0.1 ms. Which means the system could be powered off more frequently.

Besides the use of a nvFF to retain the states of the registers as described above register states can also be stored in a memory array or a hard disk through a scan chain. Storing the states to the hard disk or Flash memory array has very low on/off speed. Storing the states to a volatile memory array consumes high power during sleeping. Moreover, a volatile memory may be controlled by the processor and share the system's data bus to transfer the information. The processor consumes additional power to schedule the on/off operation and the usage of the data bus extends the on/off time.

As described in the following, according to an embodiment, a scan-based approach is used to store register states of a processing system on a resistive NVM array for low power digital circuits design. The resistive NMV array can be implemented to have much higher speed than a harddisk or a flash memory array. This allows the system to be powered off frequently. The non-volatile ability of the memory reduces the power consumption during the sleep state of the system.

According to one embodiment, a dedicated NVM array is used to store the information of the system's registers which may reduce the power consumption of the saving of the states and avoids bus access waiting times.

In the following, two schemes of the scan-based approach are described: 1. parallel writing without column address and 2. N bits parallel bus writing with column address.

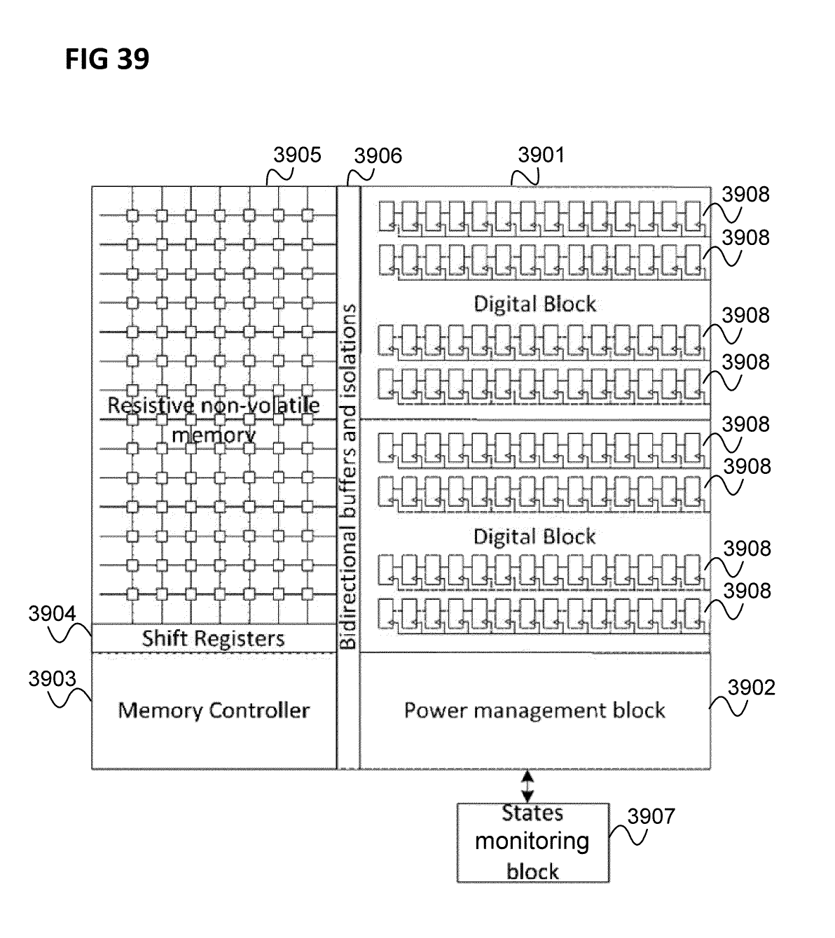

The parallel writing without column address is illustrated in FIG. 39.

FIG. 39 shows a processing system 3900 according to an embodiment.

The processing system 3900 includes a digital processing block 3901, a power management block 3902, a memory controller 3903, shift registers 3904, a resistive non-volatile memory array 3905, bidirectional drivers 3906 and a state monitoring block 3907.

The digital processing block 3901 and the power management block 3902 are not supplied with power during sleep state of the system.

The state monitoring block 3907 is always on (i.e. in both sleep and active state of the system).

The memory controller 3903, the shift registers 3904 and the resistive non-volatile memory array 3905 are on (i.e. supplied with power) during sleep state of the system and in the waking up phase (i.e. the transition from sleep state to active state).

The processing block 3901 includes a plurality of scan chains 3908, i.e. chains of serially connected flip-flops.

Communication between the memory array 3905 and the processing block 3901 is performed through the bidirectional drivers 3906. The number of columns the memory array 3905 is for example the same as the number of scan chains 3908 in the processing block 3901.

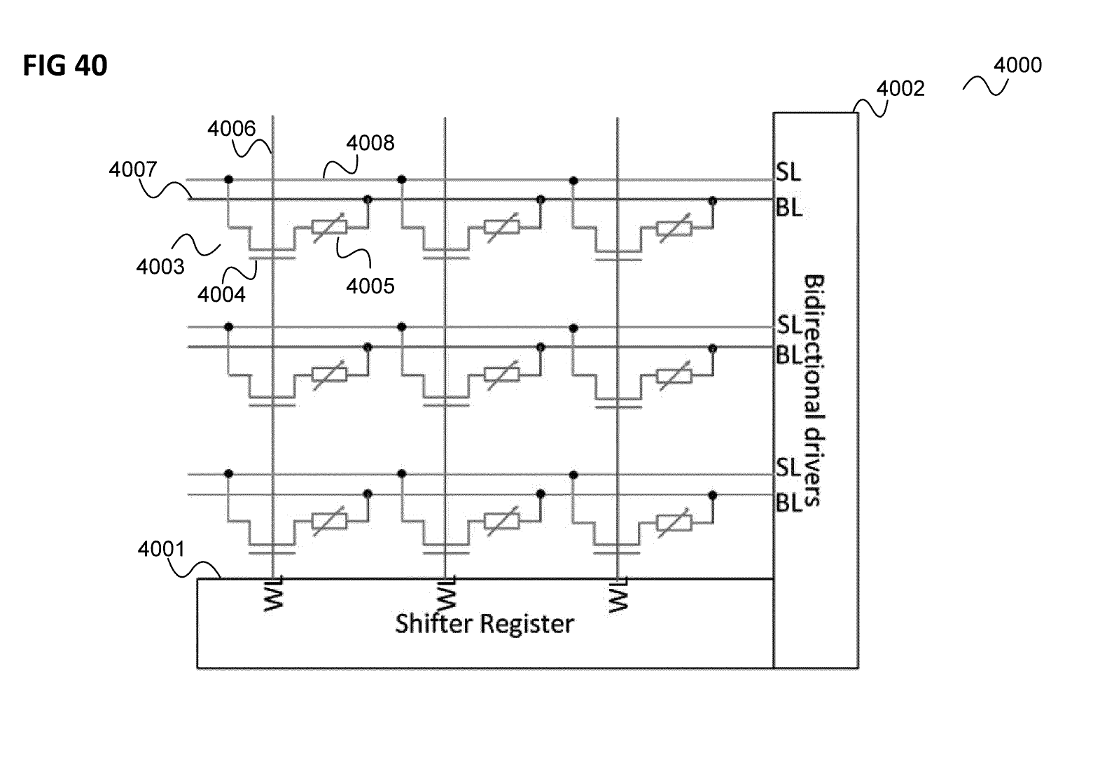

The parallel writing without column address is a fast read/write scheme which needs more energy during transition compared to the second scheme. The non-volatile memory is for example embedded with digital circuits of the processing block 3908. The memory array 3905 is illustrated in more detail in FIG. 40.

FIG. 40 shows a memory arrangement 4000 for a parallel writing without column address scheme.

The memory arrangement 4000 includes shift registers 4001 corresponding to shift registers 3903 and bidirectional drivers 4002 corresponding to the bidirectional drivers 3906.

The memory arrangement 4000 further includes an array of memory elements 4003.

Each memory element 4003 is implemented by a serial connection of an n channel FET 4004 and a switchable resistive element 4005. The gate terminals of each column of n channel FETs 4004 are connected to a word line 4006 which is connected to an stage (e.g. a flip-flop) of the shift registers 4001.

The memory elements 4003 of the same column are connected (at the side of the resistive element 4005) to a bit line 4007 which is connected to a bidirectional driver of the bidirectional drivers 4002 and (at the other side, i.e. the side of the FET 4004) to a source line 4008 which is connected to a bidirectional driver of the bidirectional drivers 4002.

According to the parallel writing without column address, row addresses but no column addresses are used which allows the memory arrangement to be simplified.

The row address is controlled by the shift register 4001. Bit line 4007 and source line 4008 are driven by the bidirectional drivers 4002.

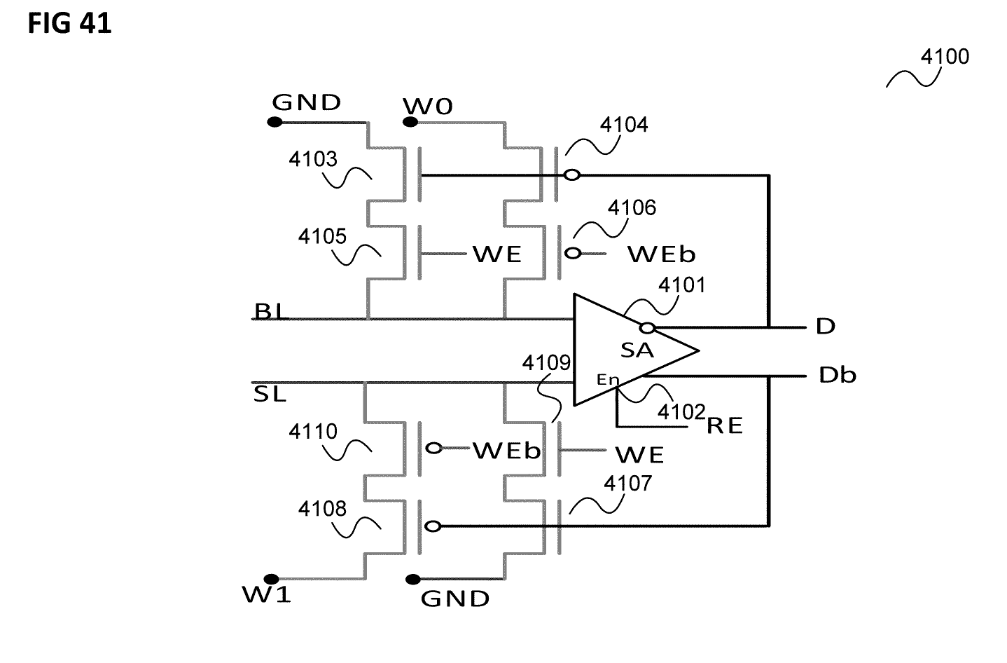

FIG. 41 shows an example for a bidirectional driver 4100 for bipolar writing according to an embodiment.

The bidirectional driver 4100 includes a sense amplifier 4101 having an first input connected to a bit line 4007 and a second input connected to a source line 4008. The sense amplifier 4101 further has an enable input 4102 supplied with a read enable signal, a D output and a Db output.

The D signal is supplied to the gate terminal of a first n channel FET 4103 and a first p channel FET 4104.

The source terminal of the first n channel FET 4103 is connected to ground and its drain terminal is connected to the source terminal of a second n channel FET 4105. The drain terminal of the second n channel FET 4105 is connected to the bit line and its gate terminal is supplied with a write enable signal WE.

The source terminal of the first p channel FET 4104 is supplied with a reset voltage W0 and its drain terminal is connected to the source terminal of a second p channel FET 4106. The drain terminal of the second p channel FET 4106 is connected to the bit line and its gate terminal is supplied with the negated write enable signal Wb.

The Db signal is supplied to the gate terminal of a third n channel FET 4107 and a third p channel FET 4108.

The source terminal of the third n channel FET 4107 is connected to ground and its drain terminal is connected to the source terminal of a fourth n channel FET 4109. The drain terminal of the fourth n channel FET 4109 is connected to the source line and its gate terminal is supplied with a write enable signal WE.

The source terminal of the third p channel FET 4108 is supplied with a set voltage W1 and its drain terminal is connected to the source terminal of a fourth p channel FET 4110. The drain terminal of the fourth p channel FET 4110 is connected to the source line and its gate terminal is supplied with the negated write enable signal Wb.

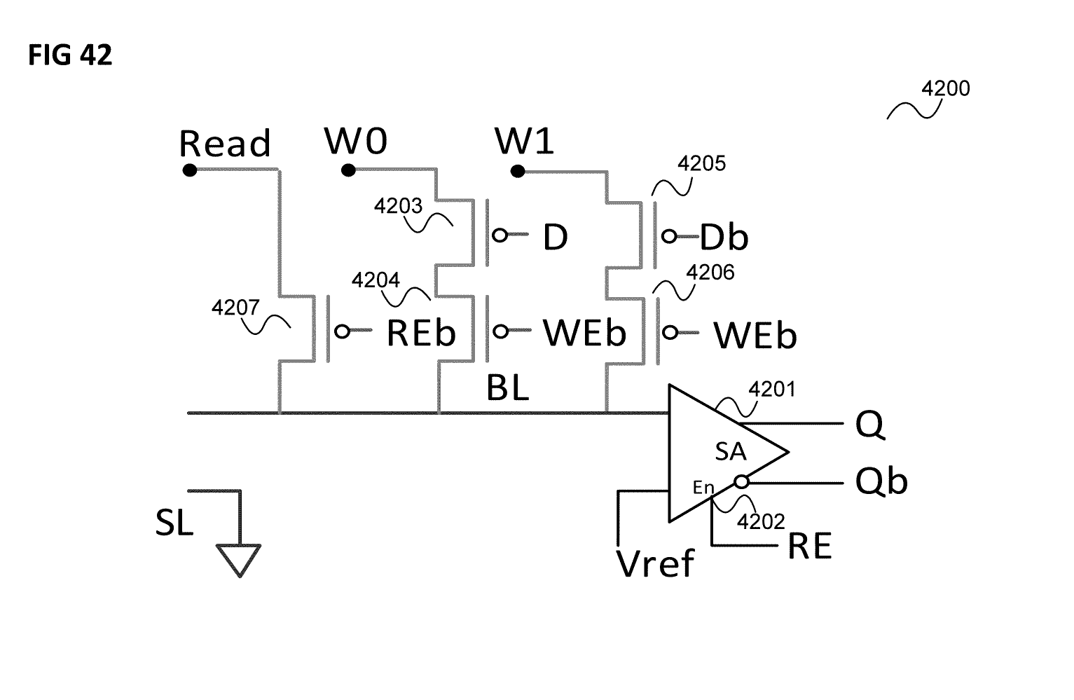

FIG. 42 shows an example for a bidirectional driver 4200 for unipolar writing according to an embodiment.

The bidirectional driver 4200 includes a sense amplifier 4201 having a first input connected to a bit line 4007 and a second input connected to a reference voltage. The source line is connected to ground.

The sense amplifier 4201 further has an enable input 4202 supplied with a read enable signal, a Q output and a Qb output.

The D signal is supplied to the gate terminal of a first p channel FET 4203.

The source terminal of the first p channel FET 4203 is supplied with a reset voltage W0 and its drain terminal is connected to the source terminal of a second p channel FET 4204. The drain terminal of the second p channel FET 4204 is connected to the bit line and its gate terminal is supplied with the negated write enable signal WEb.

The Db signal is supplied to the gate terminal of a third p channel FET 4205.

The source terminal of the third p channel FET 4205 is supplied with a reset voltage W0 and its drain terminal is connected to the source terminal of a fourth p channel FET 4206. The drain terminal of the fourth p channel FET 4206 is connected to the bit line and its gate terminal is supplied with the negated write enable signal WEb.

Further, the bit line is connected to a read output by means of a fifth p channel FET 4207 whose gate is supplied with the REb signal.

Each pair of one bit line and one source line (connected to the memory elements 4003 of the same row) is connected with one bidirectional driver (as for example shown in FIGS. 41 and 42).

The system 3900 may include a level shifter if the supply of the digital processing block 3901 is different from the supply of the memory array 3905.

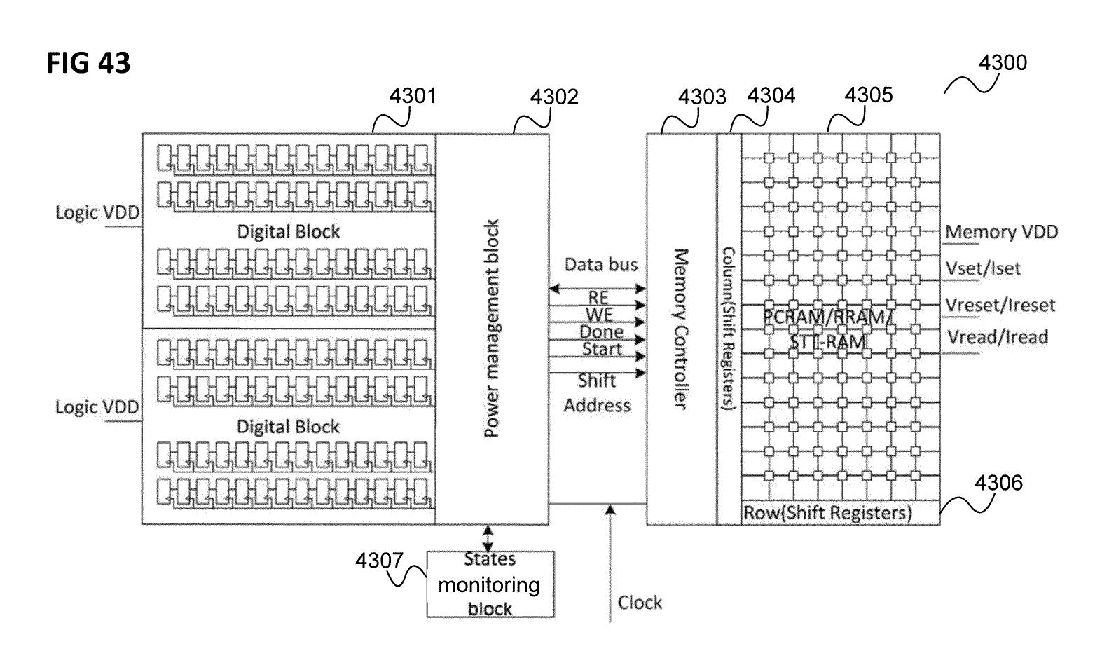

The N bits parallel bus writing with column address is illustrated in FIG. 43.

FIG. 43 shows a processing system 4300 according to an embodiment.

The processing system 4300 includes a digital processing block 4301, a power management block 4302, a memory controller 4303, column shift registers 4304, a resistive non-volatile memory array 4305, row shift registers 4306 and a state monitoring block 4307.

The digital processing block 4301 and the power management block 4302 are not supplied with power during sleep state of the system.

The state monitoring block 4307 is always on (i.e. in both sleep and active state of the system).

The memory controller 4303, the shift registers 4304, 4306 and the resistive non-volatile memory array 4305 are on (i.e. supplied with power) during sleep state of the system and in the waking up phase (i.e. the transition from sleep state to active state).

The processing block 4301 includes a plurality of scan chains 4308, i.e. chains of serially connected flip-flops.

The N bit parallel bus writing scheme as illustrated in FIG. 43 can be use both for an embedded memory array 4305 and for a standalone memory array 4305. The digital processing block 4301 for example has N scan chains (each scan chain for example with the same length) to achieve N bit parallel bus writing.

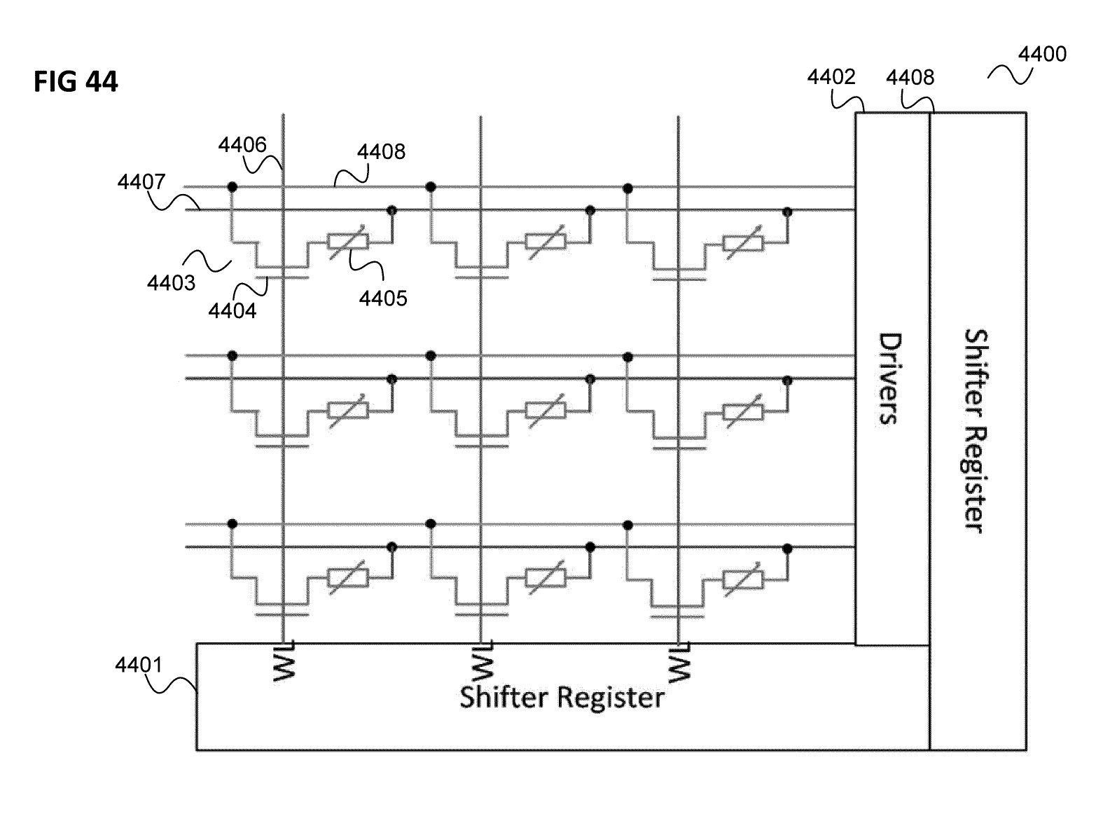

The memory array 4305 is illustrated in more detail in FIG. 44.

FIG. 44 shows a memory arrangement 4400 for a parallel writing with column address scheme.

The memory arrangement 4400 includes row shift registers 4401 corresponding to row shift registers 4304, drivers 4402 and column shift registers 4408 corresponding to column shift registers 4306.

The memory arrangement 4400 further includes an array of memory elements 4403.

Each memory element 4403 is implemented by a serial connection of an n channel FET 4404 and a switchable resistive element 4405. The gate terminals of each row of n channel FETs 4404 are connected to a word line 4406 which is connected to an stage (e.g. a flip-flop) of the shift registers 4401.

The memory elements 4403 of the same column are connected (at the side of the resistive element 4405) to a bit line 4407 which is connected to a bidirectional driver of the bidirectional drivers 4402 and (at the other side, i.e. the side of the FET 4404) to a source line 4408 which is connected to a bidirectional driver of the bidirectional drivers 4402.

The memory elements 4403 are addressed using a column address and a row address.

Bit line 4407 and source line 4408 are driven by the drivers 4402.

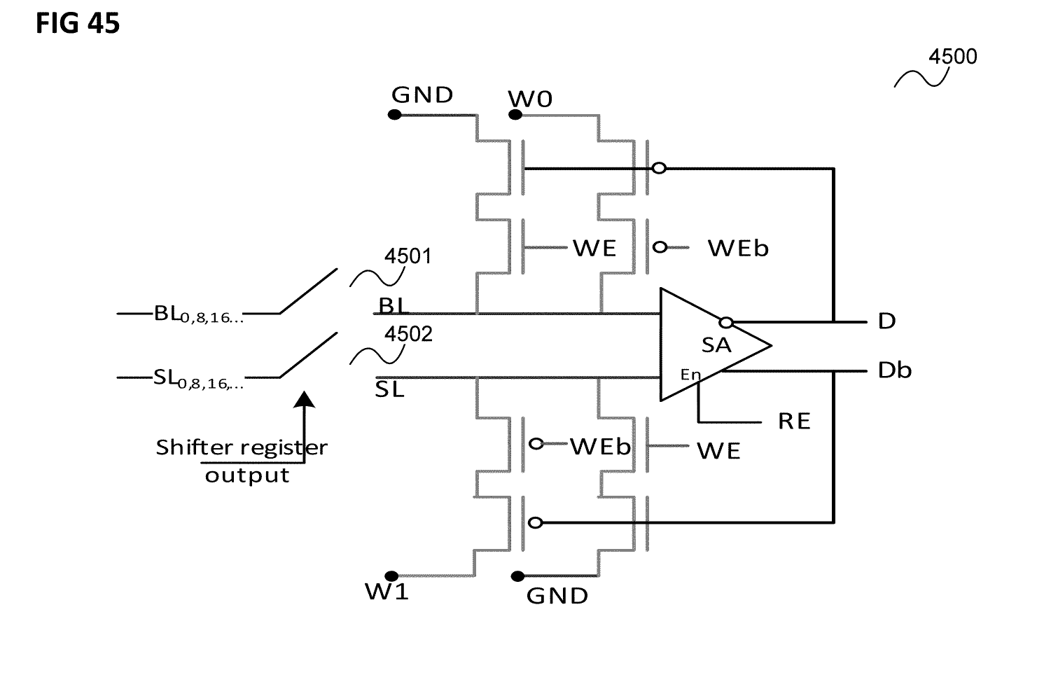

FIG. 45 shows an example for a bidirectional driver 4500 for bipolar writing according to an embodiment.

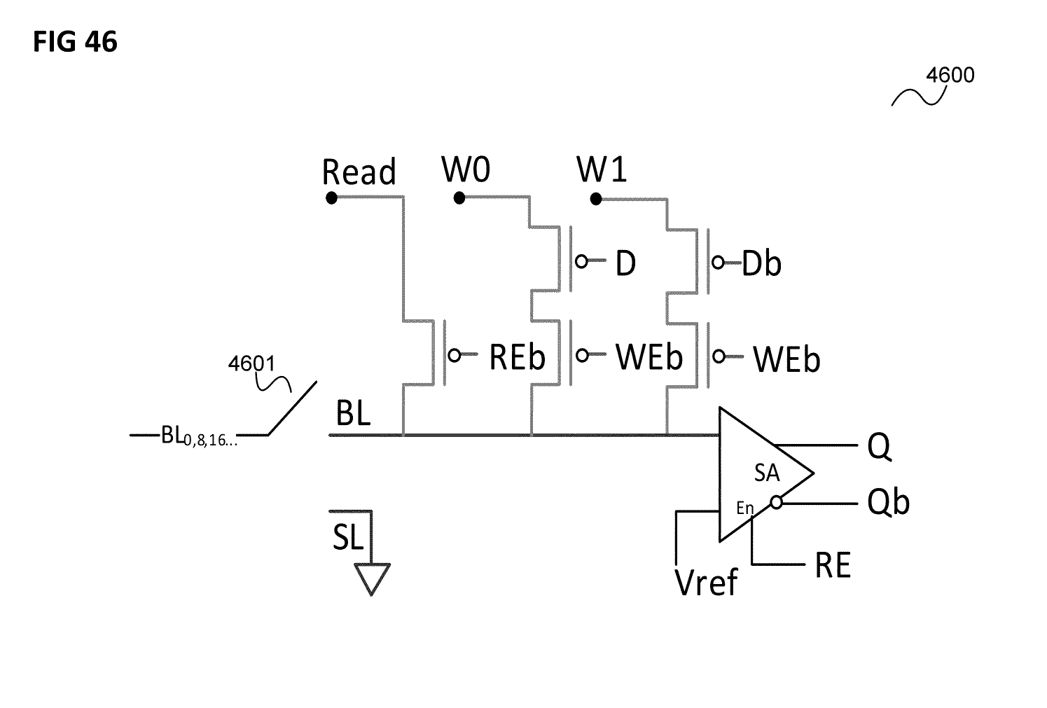

FIG. 46 shows an example for a bidirectional driver 4600 for unipolar writing according to an embodiment.

The bidirectional drivers 4500, 4600 are similar to the bidirectional drivers 4100, 4200 described above. The bidirectional drivers 4500, 4600 may however be shared among different bit lines and source lines as illustrated by switches 4501, 4502 and switch 4601.

For example, a driver driver0 of the drivers 4402 could be shared among bit lines BL0, BL8, BL16 . . . and source lines SL0, SL8, SL16 . . . for 8 bits parallel bus writing.

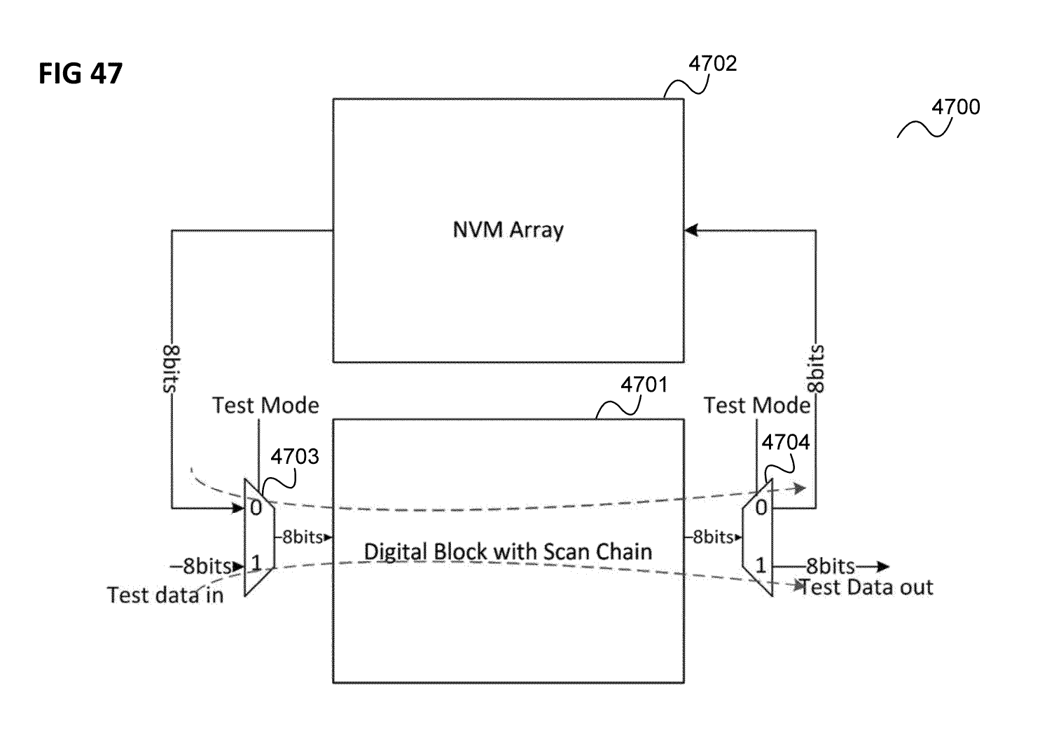

The scan chains 3908, 4308 may be used for both testing and sleeping purposes. For this, (de-)multiplexers may be added before and after the digital processing block 3901, 4301 as is shown in FIG. 47.

FIG. 47 shows a processing system 4700 according to an embodiment.

The processing system includes a digital processing block with scan chains 4701 corresponding to processing block 3901 or 4301 and a memory array 4702 corresponding to memory array 3905 or 4305.

The output of the memory array 4702 is fed to the first input of a multiplexer 4703 which may receive test data via a second input which is controlled by a test mode signal and whose output is fed to the processing block 4701.

The output of the processing block 4701 (e.g. states of a scan chain) is fed to the input of a demultiplexer 4704 which is controlled by the test mode signal and feeds its input, depending on the test mode signal, to the memory array 4702 or to a test data output.

For example, if control signal test mode is equal to 1, the system performs a test through one or more scan chains. If the control signal test mode is set to the default value 0 system can switch between sleep mode and active mode and the content (e.g. of registers) of the processing block 4701 is stored in the memory array 4702 by means of the scan chains.

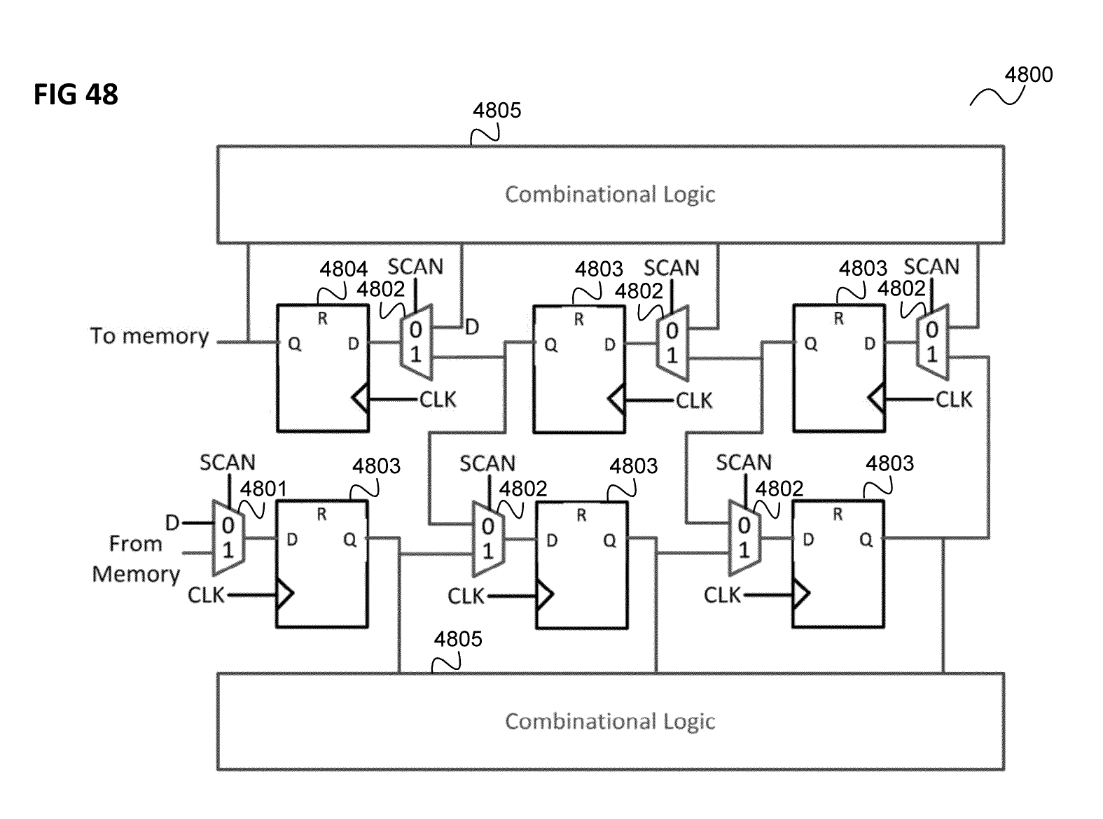

An example of a scan-based approach to store states of the digital processing block 4701 in the NVM array 4702 is shown in FIG. 48.

FIG. 48 shows a scan chain 4800 according to an embodiment.

The scan chain 4800 for example corresponds to one of the scan chains 3908, 4308.

The scan chain 4800 includes a plurality of serially connected pairs of one multiplexer 4801, 4802 preceding a flip flop 4803, 4804.

Each multiplexer 4801, 4802 has two inputs and is controlled by a SCAN signal.

The Q output of a flip-flop 4803 of a pair is connected to one of the inputs of the multiplexer of the following pair, wherein the Q output of the flip-flop 4804 of the last pair forms an output to memory.

The other input of the multiplexers 4802 (except for the multiplexer 4801 of the first pair) are connected either to a Q output of a flip-flop of a following pair or to an output of a combinational logic 4805, e.g. of digital processing block 3901, 4301. Accordingly, the Q outputs of flip-flops (except for the last flip-flop 4804) are either connected to a multiplexer of a preceding pair or an input of the combinational logic 4805.

One of the inputs of the multiplexer 4801 of the first pair forms an input from memory while the other forms a D input (e.g. for receiving data to be processed from another scan chain or component of the digital processing block).

When transitioning from active mode to sleep mode, data are written from the scan chain 4800 to a memory array (e.g. memory array 3905, 4805) through via output to memory.

The input from memory may in this case be connected to ground or used for inputting a specific pattern to give an end signal (indicating the end of the data written to memory).

When transitioning from sleep mode to active mode, data are read from the memory array through the input from memory. The output to memory may be floating in this case.

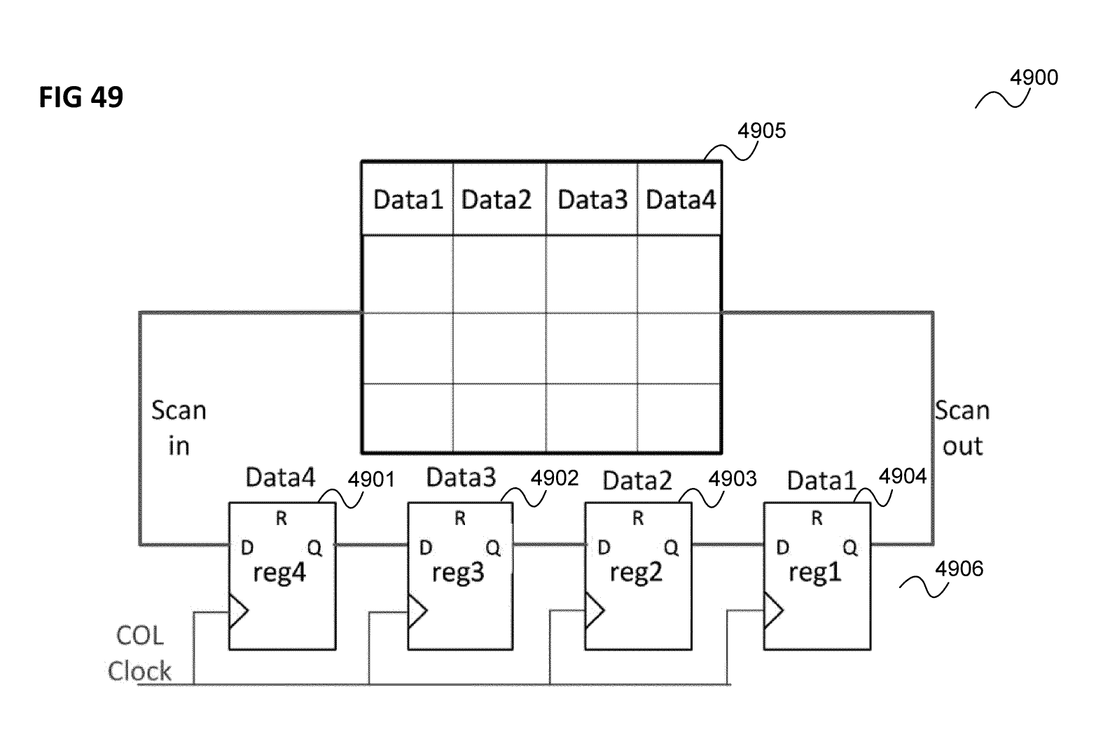

According to one embodiment, the sequence of the states of a scan chain to be stored in the memory is stored following a first in first out (FIFO) rule. This is illustrated in FIG. 49.

FIG. 49 shows an arrangement 4900 of a scan chain 4906 and a memory array 4905.

In this example, the scan chain 4906 includes four serially connected flip-flops 4901 to 4904 wherein the D input of the first flip-flop 4901 forms a D input of the scan chain 4906, the Q output of a flip-flop 4901, 4902, 4903 (except for the last flip-flop 4904) is connected to the D input of the subsequent flip-flop 4902, 4903, 4904 and the Q output of the last flip-flop 4904 forms a scan output of the scan chain 4906.

The flip-flops 4901 to 4904 are clocked with a column clock.

The memory array 4905 (e.g. corresponding to a part of memory array 3905, 4305) in this example includes 4 columns (numbered 0 to 3) and three rows (numbered 0 to 2), i.e. twelve cells numbered Mem(0, 0) to Mem(2, 3).

The scan input of the scan chain 4806 is connected to an output of the memory array 4805 and the scan output of the scan chain 4806 is connected to an input of the memory array 4805.

In this example, the data Data1 stored in the Mem(0,0) is the state of the fourth flip flop 4804 (denoted reg1), the data Data2 stored in the Mem(0,1) is the state of the third flip-flop 4803 (denoted reg2), the data Data3 stored in the Mem(0,2) is the state of the second flip-flop 4802 (denoted reg3) and the data Data3 stored in the Mem(0,3) is the state of the first flip-flop 4801 (denoted reg4).

Specifically, in the first clock cycle Data1 is read from the fourth flip-flop 4804 and stored to Mem(0,0) while Data2 is shifted to the fourth flip-flop 4804, Data3 is shifted to the third flip-flop 4803 and so on.

In the second memory address (0, 1) is selected and Data2 is written to Mem(0, 1) while the data is again shifted through scan chain.

The states of flip-flops 4801 to 4804 and the memory during the recording period are given in table 9.

TABLE 9
Data flow during recording period

| Clock | | | | | Mem | Mem | Mem | Mem |
|---|---|---|---|---|---|---|---|---|
| cycle | Reg4 | Reg3 | Reg2 | Reg1 | (0, 0) | (0, 1) | (0, 2) | (0, 3) |
| 0 | Data4 | Data3 | Data2 | Data1 | | | | |
| 1 | | Data4 | Data3 | Data2 | Data1 | | | |
| 2 | | | Data4 | Data3 | Data1 | Data2 | | |
| 3 | | | | Data4 | Data1 | Data2 | Data3 | |
| 4 | | | | | Data1 | Data2 | Data3 | Data4 |

The data flow during recovery period is the inverse of the retain (i.e. recording) period. At clock period 1, the data in Mem(0,0) is read to reg4. At clock period 2 the data in reg4 is shifted to reg3 and the data in Mem(0,1) is read to reg4. Finally the registers are restored their states. The detail data flow during restore (i.e. recovery) period is given in Table 10.

TABLE 10
Data flow during recovery period

| | Mem | Mem | Mem | Mem | | | | |
|---|---|---|---|---|---|---|---|---|
| Clock | (0, 0) | (0, 1) | (0, 2) | (0, 3) | Reg4 | Reg3 | Reg2 | Reg1 |
| 0 | Data1 | Data2 | Data3 | Data4 | | | | |
| 1 | Data1 | Data2 | Data3 | Data4 | Data1 | | | |
| 2 | Data1 | Data2 | Data3 | Data4 | Data2 | Data1 | | |
| 3 | Data1 | Data2 | Data3 | Data4 | Data3 | Data2 | Data1 | |
| 4 | Data1 | Data2 | Data3 | Data4 | Data4 | Data3 | Data2 | Data1 |

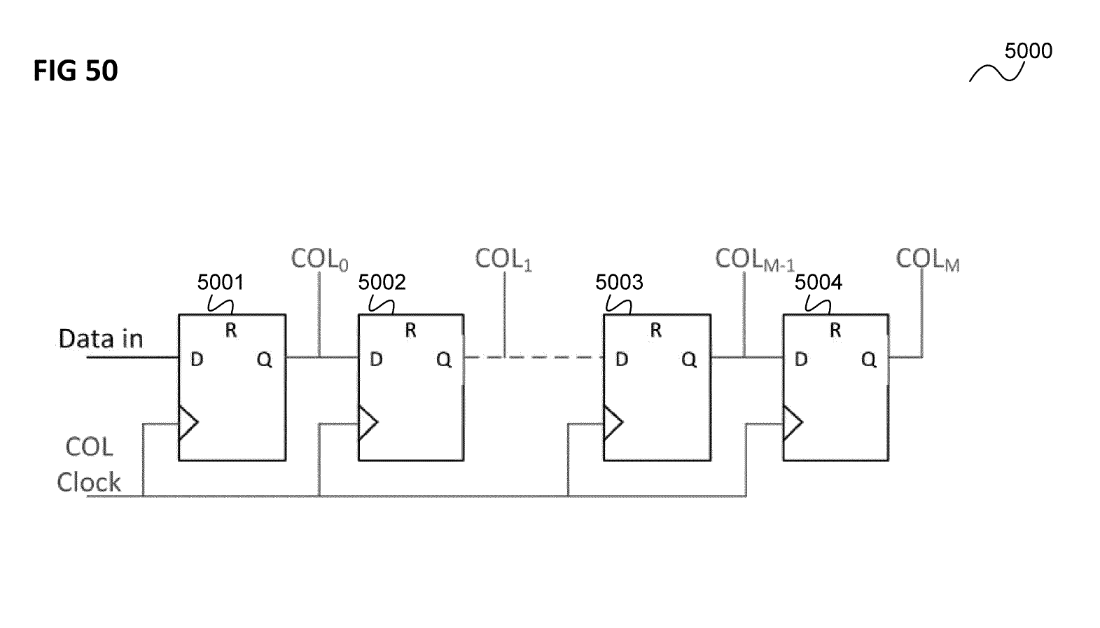

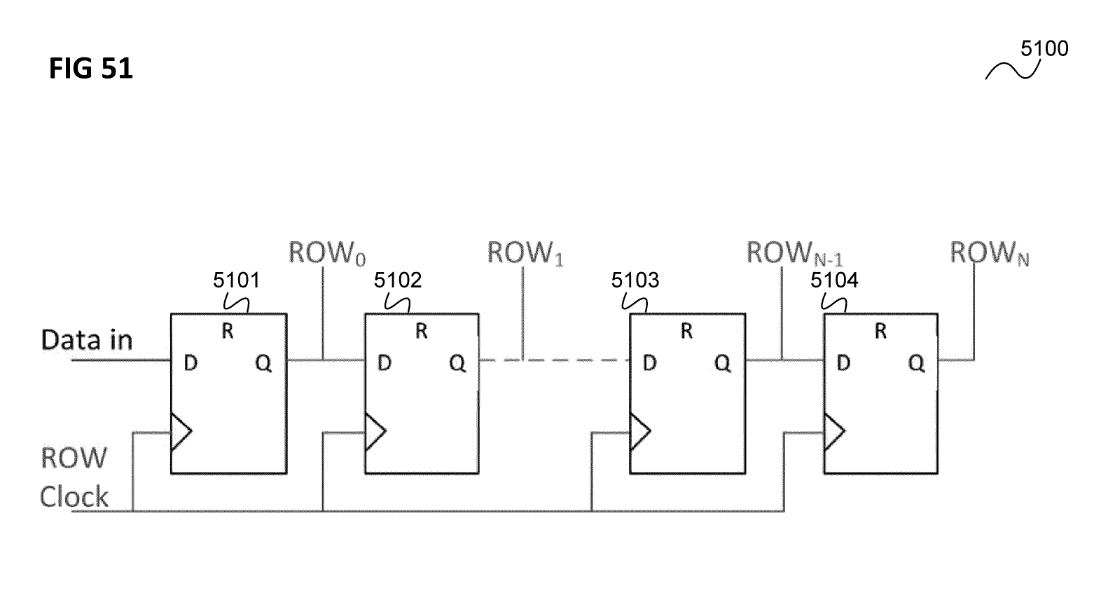

Since the memory addresses are selected in sequence, a shift register can be used as address decoder. Examples for a column shift address decoder and a row shift address decoder are shown in FIGS. 50 and 51 (for the example of a 4×4 memory array).

FIG. 50 shows a column address decoder 5000 according to an embodiment.

The decoder 5000 includes four (in general M, i.e. the number of columns) serially connected flip-flops 5001 to 5004 wherein the D input of the first flip-flop 5001 forms a D input of the decoder 5000 and the Q output of a flip-flop 5001, 5002, 5003 (except for the last flip-flop 5004) is connected to the D input of the subsequent flip-flop 5002, 5003, 5004.

The flip-flops 5001 to 5004 are clocked with a column clock.

The Q output of the first flip-flop 5001 is connected to the first column address line (e.g. word line) of memory array 4905 (i.e. for column 0).

The Q output of the second flip-flop 5002 is connected to the second column address line (e.g. word line) of memory array 4905 (i.e. for column 1).

The Q output of the third flip-flop 5003 is connected to the third column address line (e.g. word line) of memory array 4905 (i.e. for column 2).

The Q output of the fourth flip-flop 5004 is connected to the fourth column address line (e.g. word line) of memory array 4905 (i.e. for column 3).

FIG. 51 shows a row address decoder 5100 according to an embodiment.

The decoder 5100 includes four (in general N, i.e. the number of rows) serially connected flip-flops 5101 to 5104 wherein the D input of the first flip-flop 5101 forms a D input of the decoder 5100 and the Q output of a flip-flop 5101, 5102, 5103 (except for the last flip-flop 5104) is connected to the D input of the subsequent flip-flop 5102, 5103, 5104.

The flip-flops 5101 to 5104 are clocked with a row clock.

The Q output of the first flip-flop 5101 is connected to the first row address line (e.g. word line) of memory array 4905 (i.e. for row 0).

The Q output of the second flip-flop 5102 is connected to the second row address line (e.g. word line) of memory array 4905 (i.e. for row 1).

The Q output of the third flip-flop 5103 is connected to the third row address line (e.g. word line) of memory array 4905 (i.e. for row 2).

The Q output of the fourth flip-flop 5104 is connected to the fourth row address line (e.g. word line) of memory array 4905 (i.e. for row 3).

As can be seen, the column decoder 5000 and the and row decoder 5100 share the same structure in this embodiment. They differ in the clock frequency, wherein column clock frequency=M*row clock frequency, where M is the column number divided by the width N in bits of the parallel bus.

The input via the input of the decoders 5000, 5100 is the sequence 1000 (or 1000 . . . 0 (wherein the number of bits is equal to the number of columns or rows, respectively) in case of more columns/rows), i.e. only the first data bit is 1. The time between two bits of the input sequence is equal to the respective (i.e. column or row) clock period. The column data is looped through the column decoder 5000 until the row data sequence is finished or until all of the states have been stored to memory array (assuming that the number of rows is higher than the number of columns).

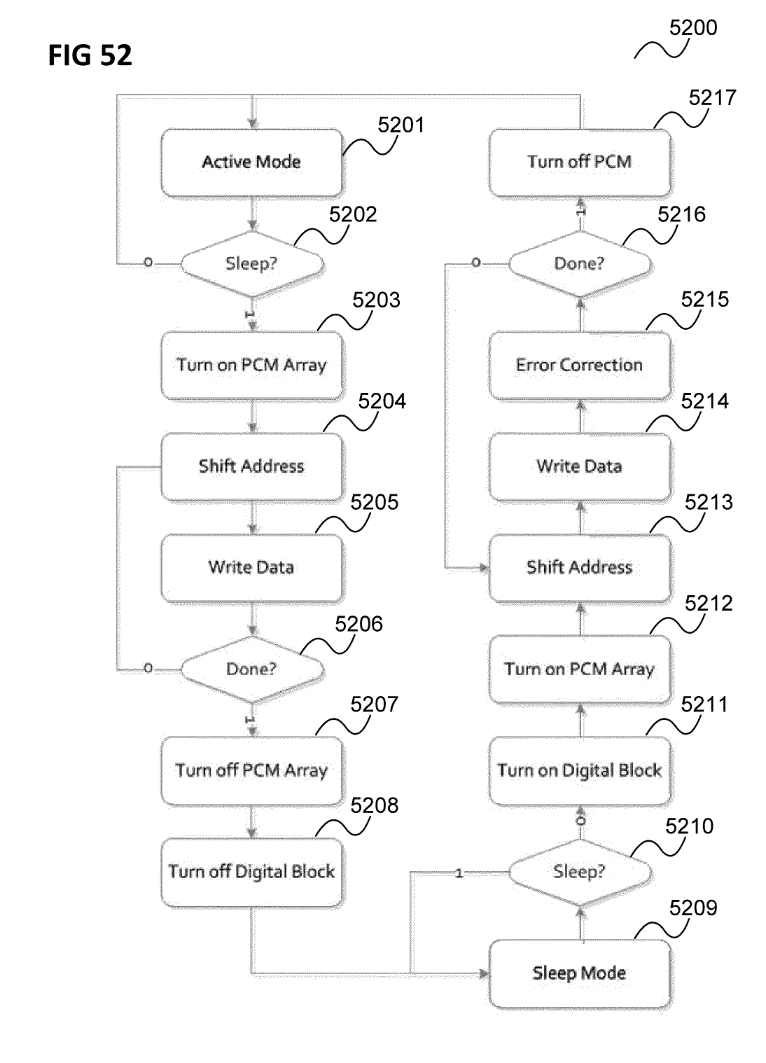

An example for a control sequence for power gating is illustrated in FIG. 52.

FIG. 52 shows a flow diagram 5200.

In 5201, the processing system is in active mode.

The transition procedure from active mode to sleep mode includes the following.

In 5202, if the state of a sleep signal is sleep=0, the state is kept at active

Once sleep=1, the memory array is turned on in 5203.

In 5204, the memory addresses is shifted (e.g. initially to (0, 0) and in later iterations from (i, j) to (i+1, j+1)).

In 5205, the data from the last flip-flop of the scan-chain is written to the memory array and the states of the flip-flops are shifted through the scan chain.

In 5206, 5204 and 5205 are repeated until the states of all flip-flops of the scan chain have been written into the memory array.

In 5207, the memory array is turned off.

In 5208, the digital processing block is turned off.

IN 5209, sleep mode is entered.

The transitioning procedure from sleep mode to active mode is similar includes the following.

In 5210, at sleep mode, if sleep=1 the state of the processing system is kept at sleep mode.

In 5211, once sleep=0, the digital processing block is turned on first.

In 5212, the memory array is turned on.

In 5213, the memory address is shifted.

In 5214, data is read from the memory array to first-flop of the scan chain.

In 5215, error correction is performed on the read data.

In 5216, the states of the flip-flops are shifted through the scan chain and 5213 to 5215 are repeated until all of the states have been restored to flip-flops.

In 5217, the memory array is turned off and active mode is entered in 5201.

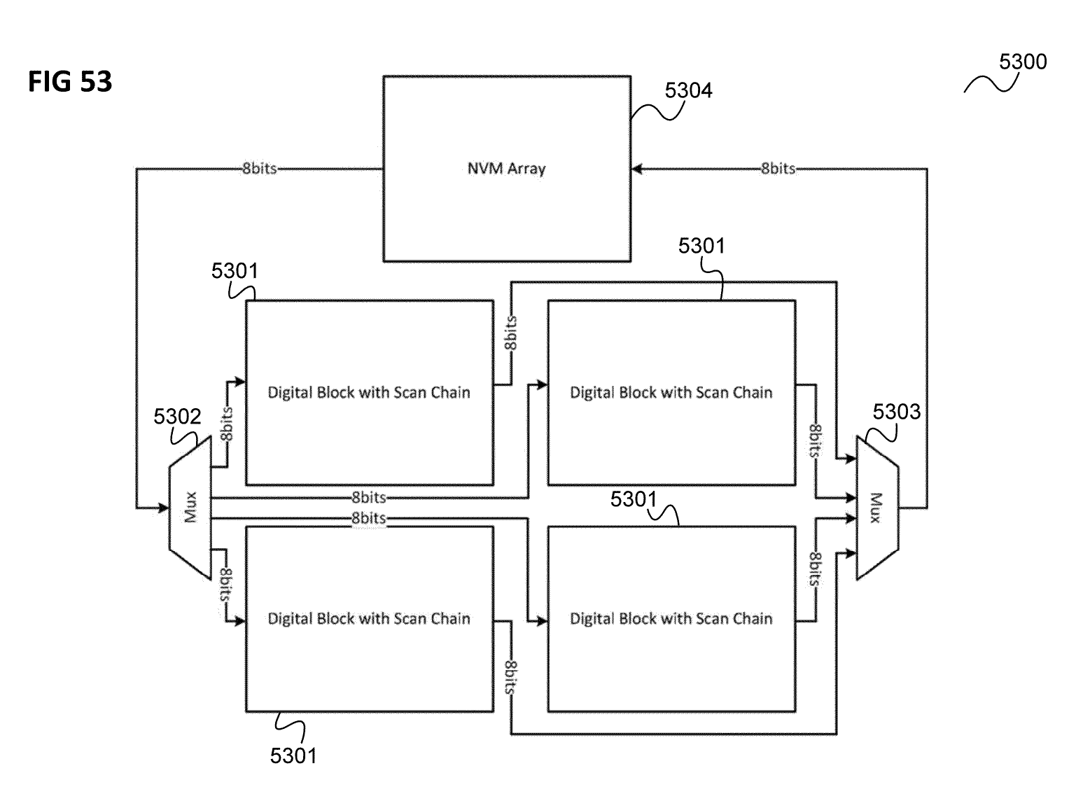

FIG. 53 shows a scan chain arrangement 5300 illustrating that in the N bit parallel bus writing scheme a memory array can be shared among a plurality of digital blocks, e.g. in case of using a dedicated memory array.

The scan chain arrangement 5300 includes a plurality of digital processing blocks with scan chains 5301 similar to digital processing block with scan chains 4701.

Each digital processing block 5301 has an input coupled with a respective output of a demultiplexer 5302 and has an output coupled with a respective input of a multiplexer 5303. The input of the demultiplexer 5302 is coupled with an output of a memory array 5304 (e.g. similar to memory array 4702) and the output of the multiplexer 5303 is coupled with an input of the memory array 5304.

The number of non-volatile memory cells of the memory array is for example selected to be no less than the number of register cells in the digital blocks whose states should be retained. The sharing of the memory array among a plurality of digital processing blocks is for example only done when the total number of registers in the digital processing blocks going to sleep state is less than the number of cells of the memory array.

An ECC (error correction code) module can be inserted in the memory control block (e.g. memory control block 3903, 4303) to enhance the reliability of the memory array. The minimum standby time is similar to the non-volatile flip-flop of the second form described above. The memory array allows a more compact implementation than using non-volatile flip-flops in the processing blocks since the drivers and sense amplifiers may be shared. However, the retaining and restore speed are lower than in case of using non-volatile flip-flops in the processing blocks because the states are sequentially retained and restored. However, the minimum standby time, which is determined by the retain power and restore power, may be longer than the total retain and restore time.

In summary, according to one embodiment, a data processing system is provided including a data processing circuit including a scan chain, a non-volatile memory and a controller configured to store, in response to a signal indicating that the data processing system is entering sleep mode, the content of the scan chain in the memory and to read, in response to a signal indicating the data processing system is leaving sleep mode, data from the memory and to store the data in the scan chain.

The memory is for example a memory based on switchable resistive elements including material showing a resistive switching effect.

The controller is for example configured to store the content of the scan chain in the memory by shifting the content through the scan chain into the memory.

The controller is for example configured to store the data read from the memory in the scan chain by shifting the data into the scan chain.

The latch circuit may further include a plurality of scan chains and the controller may be configured to store, in response to a signal indicating that the data processing system is entering sleep mode, the contents of the scan chains in parallel in the memory and to read, in response to a signal indicating the data processing system is leaving sleep mode, data from the memory and to store the data in parallel in the scan chains.

According to another embodiment, a method for entering and leaving a sleep mode is provided including storing, in response to a signal indicating that a data processing system is entering sleep mode, the content of a scan chain of the data processing system in a non-volatile memory and reading, in response to a signal indicating the data processing system is leaving sleep mode, data from the memory and storing the data in the scan chain.

Examples given in context of the processing system are analogously valid for the method for entering and leaving a sleep mode.

While specific embodiments have been described, it should be understood by those skilled in the art that various changes in form and detail may be made therein without departing from the spirit and scope of the aspects of this disclosure as defined by the appended claims. The scope is thus indicated by the appended claims and all changes which come within the meaning and range of equivalency of the claims are therefore intended to be embraced.

1. A latch circuit comprising
a switchable resistive element; and
a switching circuit configured to set the switchable resistive element to a first resistive state in response to receiving a set signal and to set the switchable resistive element to a second resistive state in response to receiving a reset signal.

2. The latch circuit according to claim 1, comprising an input configured to receive a signal, wherein the set signal corresponds to the signal having a first value and the reset signal corresponds to the signal having a second value.

3. The latch circuit according to claim 2, wherein one of the first value and the second value is a logical 1 and the other of the first value and the second value is a logical 0.

4. The latch circuit according to claim 1, further comprising a set input and a reset input, wherein the switching circuit is configured to set the switchable resistive element to a first resistive state in response to receiving the set signal and to set the switchable resistive element to a second resistive state in response to receiving the reset signal via the reset input.

5. The latch circuit according to claim 1, wherein the switching circuit is configured to detect whether the switchable resistive element is in the first resistive state and to switch the switchable resistive element into the first resistive state in response to receiving a set signal if it has detected that the switchable resistive element is not in the first resistive state.

6. The latch circuit according to claim 1, wherein the switching circuit is configured to detect whether the switchable resistive element is in the second resistive state and to switch the switchable resistive element into the second resistive state in response to receiving a reset signal if it has detected that the switchable resistive element is not in the second resistive state.

7. The latch circuit according to claim 1, wherein the switchable resistive element comprises material showing a resistive switching effect.

8. The latch circuit according to claim 1, wherein the switchable resistive element comprises phase change material.

9. The latch circuit according to claim 1, wherein the switching circuit is configured to set the switchable resistive element to the first resistive state by a applying a first voltage or current to the switchable resistive element and to reset the switchable resistive element to the second resistive state by a applying a second voltage or current to the switchable resistive element.

10. The latch circuit according to claim 9, wherein the first voltage or current and the second voltage or current differ in at least one of magnitude and polarity.

11. The latch circuit according to claim 1, further comprising an output circuit configured to output a signal representing the resistive state of the switchable resistive element.

12. The latch circuit according to claim 11, wherein the output circuit comprises a slave latch.

13. The latch circuit according to claim 1, further comprising an input circuit configured to receive an input and to provide, depending on the input, the set signal or the reset signal to the switching circuit.

14. The latch circuit according to claim 13, wherein the input circuit comprises a master latch.

15. A data processing system comprising
a data processing circuit comprising a scan chain;
a non-volatile memory;
a controller configured to store, in response to a signal indicating that the data processing system is entering sleep mode, the content of the scan chain in the memory and to read, in response to a signal indicating the data processing system is leaving sleep mode, data from the memory and to store the data in the scan chain.

16. The latch circuit according to claim 15, wherein the memory is a memory based on switchable resistive elements comprising material showing a resistive switching effect.

17. The latch circuit according to claim 15, wherein the controller is configured to store the content of the scan chain in the memory by shifting the content through the scan chain into the memory.

18. The latch circuit according to claim 15, wherein the controller is configured to store the data read from the memory in the scan chain by shifting the data into the scan chain.

19. The latch circuit according to claim 15, comprising a plurality of scan chains wherein the controller is configured to store, in response to a signal indicating that the data processing system is entering sleep mode, the contents of the scan chains in parallel in the memory and to read, in response to a signal indicating the data processing system is leaving sleep mode, data from the memory and to store the data in parallel in the scan chains.

20. A method for entering and leaving a sleep mode comprising:
storing, in response to a signal indicating that a data processing system is entering sleep mode, the content of a scan chain of the data processing system in a non-volatile memory and
reading, in response to a signal indicating the data processing system is leaving sleep mode, data from the memory and storing the data in the scan chain.
